(19) United States
(12) Patent Application Publication
(10) Pub. No.: US 2026/0114133 A1
(43) Pub. Date: Apr. 23, 2026

(54) DISPLAY PANEL AND DISPLAY DEVICE

(71) Applicants: Wuhan Tianma MicroElectronics Co., Ltd. Shanghai Branch., Shanghai (CN); Wuhan Tianma Micro-Electronics Co., Ltd., Wuhan (CN)

(72) Inventors: Shaowei LIU, Shanghai (CN); Chong Qian, Shanghai (CN); Ye Jin, Shanghai (CN)

(21) Appl. No.: 19/182,161

(22) Filed: Apr. 17, 2025

(30) Foreign Application Priority Data
Oct. 23, 2024 (CN) 202411489824.X

(51) Int. Cl. H10K 59/123; H10K 59/121; H10K 59/131; H10K 102/00

(52) U.S. Cl. CPC H10K 59/123; H10K 59/1213; H10K 59/131; H10K 2102/3031

(57) ABSTRACT

A display panel includes a transparent display area, a wiring area, a transitional display area, and a regular display area, where the transitional display area at least partially surrounds the transparent display area, the wiring area is located between the transparent display area and the transitional display area and between the transitional display area and the regular display area, the regular display area at least partially surrounds the transitional display area and the transparent display area, and a light transmittance of the transparent display area is greater than that of the regular display area. Along a first direction, the transitional display area is located between the first regular display area and the transparent display area. Along a second direction, a difference between the numbers of levels of the pixel-driving circuit in the first regular display area and the transitional display area is less than a predefined number of levels.

### CROSS-REFERENCE TO RELATED APPLICATION

This application claims the priority of Chinese Patent Application No. 202411489824.X, filed on Oct. 23, 2024, the content of which is incorporated herein by reference in its entirety.

### TECHNICAL FIELD

The present application relates to the field of display technology, and in particular to a display panel and a display device.

### BACKGROUND

In electronic devices including display panels, the pursuit of a high screen-to-body ratio with a better visual experience has become one of the current trends in the development of display technology. A transparent display area may be arranged in a display panel, and sensors such as image acquisition apparatus may be arranged under the screen of a transparent display area to better achieve a full-screen design.

In the existing technologies, for display panels with transparent display areas, the pixel-driving circuits of display panels with low pixels per inch (PPI) are generally compressed to leave transparent display areas, while for display panels with higher PPI, their pixel-driving circuits cannot be compressed any further. If the pixel-driving circuits in the transitional display areas are scaled down, which makes the number of levels of pixel-driving circuit in the transitional display areas differ greatly from that in the regular display areas, the display difference between the transitional display areas and the regular display areas will be too large, causing problems such as color cast on the display panels.

### SUMMARY

To solve the above technical problems, the present disclosure provides a display panel and a display device, which reserve layout space for a transparent display area and optimize the display performance of the display panel.

In one aspect, the present disclosure provides a display panel, including a transparent display area, a wiring area, a transitional display area, and a regular display area, where the transitional display area at least partially surrounds the transparent display area, the regular display area at least partially surrounds the transitional display area and the transparent display area, a light transmittance of the transparent display area is greater than a light transmittance of the regular display area, and the wiring area is located between the transparent display area and the transitional display area and between the transitional display area and the regular display area; and pixel-driving circuits and light-emitting elements electrically connected to the pixel-driving circuits, where the pixel-driving circuits are disposed in the transitional display area and the regular display area, and the light-emitting elements are disposed in the transparent display area, the wiring area, the transitional display area, and the regular display area. The regular display area includes a first regular display area, along a first direction, the transitional display area is located between the first regular display area and the transparent display area, along a second direction, a number of levels of pixel-driving circuit in the first regular display area is a first number of levels, and a number of levels of pixel-driving circuit in the transitional display area is a second number of levels, the first direction is a direction from the transitional display area to the transparent display area, and the second direction intersects with the first direction. A difference between the first number of levels and the second number of levels is smaller than a predefined level, and the predefined level is equal to or smaller than ½ of the first number of levels.

In another aspect, the present disclosure further provides a display device, including a display panel, where the display panel includes a transparent display area, a wiring area, a transitional display area, and a regular display area, where the transitional display area at least partially surrounds the transparent display area, the regular display area at least partially surrounds the transitional display area and the transparent display area, a light transmittance of the transparent display area is greater than a light transmittance of the regular display area, and the wiring area is located between the transparent display area and the transitional display area and between the transitional display area and the regular display area; and pixel-driving circuits and light-emitting elements electrically connected to the pixel-driving circuits, where the pixel-driving circuits are disposed in the transitional display area and the regular display area, and the light-emitting elements are disposed in the transparent display area, the wiring area, the transitional display area, and the regular display area. The regular display area includes a first regular display area, along a first direction, the transitional display area is located between the first regular display area and the transparent display area, along a second direction, a number of levels of pixel-driving circuit in the first regular display area is a first number of levels, and a number of levels of pixel-driving circuit in the transitional display area is a second number of levels, the first direction is a direction from the transitional display area to the transparent display area, and the second direction intersects with the first direction. A difference between the first number of levels and the second number of levels is smaller than a predefined level, and the predefined level is equal to or smaller than ½ of the first number of levels provided in the first aspect.

Other features of the present disclosure and advantages thereof will become apparent from the following detailed description of exemplary embodiments of the present disclosure with reference to the accompanying drawings.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure.

To more clearly illustrate the embodiments of the present disclosure or the technical solutions to the existing technologies, the drawings essential for use in the embodiments or the description of the existing technologies will be briefly introduced below.

Obviously, for a person skilled in the art, other drawings may be obtained based on these drawings without making creative efforts.

FIG. 1 is a schematic diagram of a top view of a display panel in accordance with an embodiment of the present disclosure;

FIG. 2 is a schematic diagram of a partial structure of a display panel in accordance with an embodiment of the present disclosure;

FIG. 3 is a schematic diagram of a partial structure of another display panel in accordance with an embodiment of the present disclosure;

FIG. 4 is a schematic diagram of a partial structure of another display panel in accordance with an embodiment of the present disclosure;

FIG. 5 is a schematic diagram of a partial structure of another display panel in accordance with an embodiment of the present disclosure;

FIG. 6 is a schematic diagram of a partial structure of another display panel in accordance with an embodiment of the present disclosure;

FIG. 7 is a schematic diagram of a partial structure of another display panel in accordance with an embodiment of the present disclosure;

FIG. 8 is a schematic diagram of a partial structure of another display panel in accordance with an embodiment of the present disclosure;

FIG. 9 is a partial enlarged schematic diagram of area B1 in FIG. 8;

FIG. 10 is a schematic structural diagram of a pixel-driving circuit in a transitional display area in accordance with an embodiment of the present disclosure;

FIG. 11 is a schematic structural diagram of a pixel-driving circuit in a regular display area in accordance with an embodiment of the present disclosure;

FIG. 12 is a schematic diagram of a circuit structure of a pixel-driving circuit in accordance with an embodiment of the present disclosure;

FIG. 13 is a schematic diagram of a cross-sectional structure of a display panel in accordance with an embodiment of the present disclosure;

FIG. 14 is a schematic diagram of a planar structure of a bottom shielding metal layer of a driving repetitive unit in accordance with an embodiment of the present disclosure;

FIG. 15 is a schematic diagram of a planar structure of a first active layer of a driving repetitive unit in accordance with an embodiment of the present disclosure;

FIG. 16 is a schematic diagram of a planar structure of a first metal layer of a driving repetitive unit in accordance with an embodiment of the present disclosure;

FIG. 17 is a schematic diagram of a planar structure of a capacitor metal layer of a driving repetitive unit in accordance with an embodiment of the present disclosure;

FIG. 18 is a schematic diagram of a planar structure of a second active layer of a driving repetitive unit in accordance with an embodiment of the present disclosure;

FIG. 19 is a schematic diagram of a planar structure of a second metal layer of a driving repetitive unit in accordance with an embodiment of the present disclosure;

FIG. 20 is a schematic diagram of a planar structure of a third metal layer of a driving repetitive unit in accordance with an embodiment of the present disclosure;

FIG. 21 is a schematic diagram of a planar structure of a first planarization layer of a driving repetitive unit in accordance with an embodiment of the present disclosure;

FIG. 22 is a schematic diagram of a planar structure of a fourth metal layer of a driving repetitive unit in accordance with an embodiment of the present disclosure;

FIG. 23 is a schematic diagram of a planar structure of a second planarization layer in accordance with an embodiment of the present disclosure;

FIG. 24 is a schematic diagram of a planar structure of a first conductive layer in accordance with an embodiment of the present disclosure;

FIG. 25 is a schematic diagram of a planar structure of a third planarization layer in accordance with an embodiment of the present disclosure;

FIG. 26 is a schematic diagram of a planar structure of a second conductive layer in accordance with an embodiment of the present disclosure;

FIG. 27 is a schematic diagram of a planar structure of a fourth planarization layer in accordance with an embodiment of the present disclosure;

FIG. 28 is a schematic diagram of a planar structure of a third conductive layer in accordance with an embodiment of the present disclosure;

FIG. 29 is a schematic diagram of a partial structure of another display panel in accordance with an embodiment of the present disclosure;

FIG. 30 is a partial enlarged schematic diagram of area B2 in FIG. 29;

FIG. 31 is a schematic diagram of a planar structure of a power signal line in accordance with an embodiment of the present disclosure;

FIG. 32 is a schematic diagram of a cross-sectional structure of a display panel in accordance with an embodiment of the present disclosure;

FIG. 33 is a schematic diagram of a cross-sectional structure of another display panel in accordance with an embodiment of the present disclosure;

FIG. 34 is another partial enlarged schematic diagram of area B2 in FIG. 29;

FIG. 35 is a schematic diagram of a partial structure of another display panel in accordance with an embodiment of the present disclosure;

FIG. 36 is a schematic structural diagram of a light-emitting repetitive unit in accordance with an embodiment of the present disclosure;

FIG. 37 is a partial enlarged schematic diagram of area B3 in FIG. 29;

FIG. 38 is a schematic diagram of a film layer of a light-emitting repetitive unit in accordance with an embodiment of the present disclosure;

FIG. 39 is a schematic structural diagram of a driving repetitive unit in accordance with an embodiment of the present disclosure;

FIG. 40 is a schematic diagram of a film structure of a light-emitting repetitive unit in accordance with an embodiment of the present disclosure;

FIG. 41 is a schematic diagram of a film layer structure from a transitional display area to a transparent display area in accordance with an embodiment of the present disclosure;

FIG. 42 is a schematic diagram of a partial structure of another display panel in accordance with an embodiment of the present disclosure;

FIG. 43 is a schematic diagram of a partial structure of another display panel in accordance with an embodiment of the present disclosure; and

FIG. 44 is a schematic structural diagram of a display device in accordance with an embodiment of the present disclosure.

### DETAILED DESCRIPTION

To more clearly understand the objective, features, and advantages of the present disclosure, the embodiments of the present disclosure will be further described below. It should be noted that the embodiments of the present disclosure and the features in the embodiments may be combined with each other without conflict.

In the following description, many specific details are set forth to facilitate a comprehensive understanding of the present disclosure, but the present disclosure may also be implemented in other ways different from those described herein. It is apparent that the embodiments in the specification are only part of the embodiments of the present disclosure, rather than all of the embodiments.

In the existing technologies, for display panels with transparent display area, the pixel-driving circuits for a display panel with a low PPI are generally compressed to leave a transparent display area, while for a display panel with a high PPI, its pixel-driving circuits cannot be compressed any further. If the pixel-driving circuits in a transitional display area are scaled down that makes the number of levels of pixel-driving circuit in the transitional display area differ greatly from that in a regular display area, the display difference between the transitional display area and the regular display area will be too large, causing problems such as color cast on the display panel.

To solve the above problems, the embodiments of the present disclosure provide a display panel, including a transparent display area, a wiring area, a transitional display area, and a regular display area, where the transitional display area at least partially surrounds the transparent display area, and the regular display area at least partially surrounds the transitional display area and the transparent display area. The light transmittance of the transparent display area is greater than the light transmittance of the regular display area. The wiring area is located between the transparent display area and the transitional display area, and between the transitional display area and the regular display area. For pixel-driving circuits and light-emitting elements electrically connected to the pixel-driving circuits, the pixel-driving circuits are disposed in the transitional display area and the regular display area, and the light-emitting elements are disposed in the transparent display area, the wiring area, the transitional display area, and the regular display area. The regular display area includes a first regular display area.

Along a first direction, the transitional display area is located between the first regular display area and the transparent display area. In a second direction, the number of levels of pixel-driving circuit in the first regular display area is a first number of levels, and the number of levels of pixel-driving circuit in the transitional display area is a second number of levels. The first direction is a direction from the transitional display area to the transparent display area, and the second direction intersects with the first direction. The difference between the first number of levels and the second number of levels is less than a predefined number, where the predefined number is equal to or less than ½ of the first number of levels. Thus, the problem of color cast on the display panel caused by the excessive difference in the numbers of levels of the pixel-driving circuit in the second direction between the transitional display area and the regular display area is avoided, which not only leaves layout space for the transparent display area in the display panel, but also improves the display performance of the display panel.

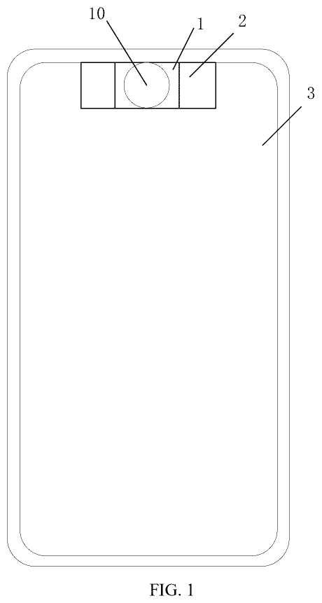

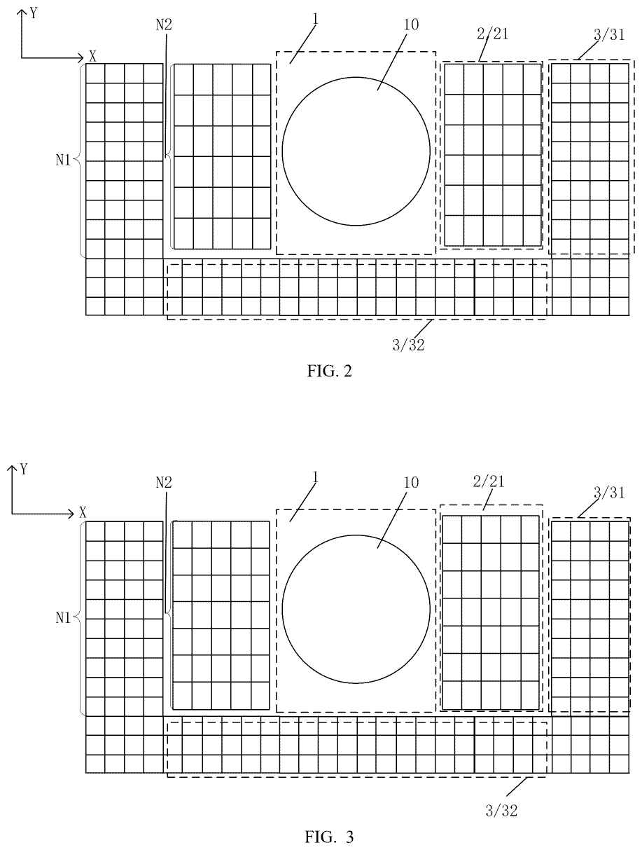

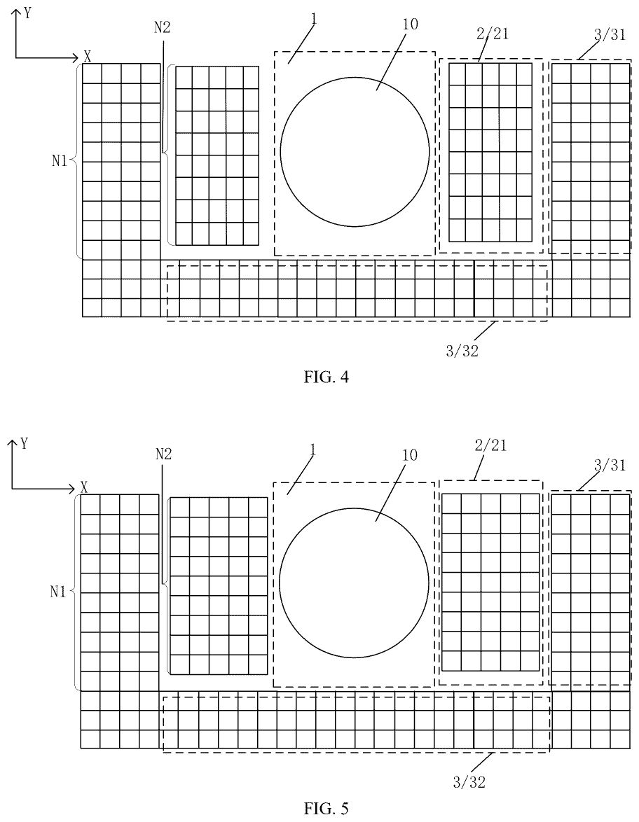

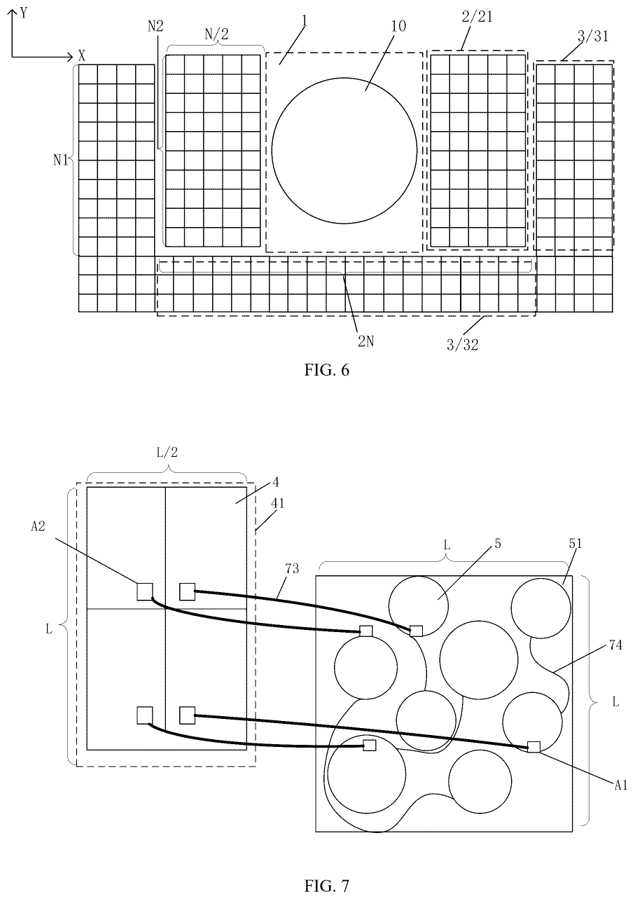

FIG. 1 is a schematic diagram of a top view of a display panel in accordance with an embodiment of the present disclosure, FIG. 2 is a schematic diagram of a partial structure of a display panel in accordance with an embodiment of the present disclosure, FIG. 3 is a schematic diagram of a partial structure of another display panel in accordance with an embodiment of the present disclosure, FIG. 4 is a schematic diagram of a partial structure of another display panel in accordance with an embodiment of the present disclosure, FIG. 5 is a schematic diagram of a partial structure of another display panel in accordance with an embodiment of the present disclosure, and FIG. 6 is a schematic diagram of a partial structure of another display panel in accordance with an embodiment of the present disclosure. FIG. 1 exemplarily shows that the wiring area 1 is located between the transparent display area 10 and the transitional display area 2, and FIG. 2 also shows that the wiring area 1 is also located between the transitional display area 2 and the regular display area 3.

The transitional display area 2 is located on both sides of the wiring area 1 along the first direction X. In some embodiments, the transitional display area 2 may also be arranged around the wiring area 1, that is, the transitional display area 2 is located on both sides of the wiring area 1 along the first direction X, and the transitional display area 2 is located on both sides of the wiring area 1 along the second direction Y. In addition, FIG. 1 also exemplarily shows that the regular display area 3 is arranged on both sides of the transitional display area 2 and the wiring area 1 along the first direction X, and is arranged on one side of the transitional display area 2 and the wiring area 1 in the second direction Y. In some embodiments, the regular display area 3 may also be arranged on both sides of the transitional display area 2 and the wiring area 1 in the second direction Y.

Exemplarily, light-emitting elements are arranged in the wiring area 1, the transparent display area 10, the transitional display area 2, and the regular display area 3 (the structure of the light-emitting elements is not specifically shown in FIGS. 1 to 6). No pixel-driving circuit 4 is configured in the transparent display area 100, so that the circuit structure of the transparent display area 10 is minimal, thereby having a higher light transmittance. The light transmittance of the transparent display area 10 is greater than the light transmittance of the regular display area 3. Exemplarily, the transparent display area 10 may be used for display or for light transmission. For example, the transparent display area 10 may be used to realize functions such as image acquisition or fingerprint recognition, which is not limited in the present disclosure.

The transitional display area 2 is provided with pixel-driving circuits 4 for driving the light-emitting elements of the transparent display area 10 and the wiring area 1 to emit light, and is also provided with pixel-driving circuits 4 for driving the light-emitting elements of the transitional display area 2 to emit light. The transitional display area 2 may be light-transmissive or light-impermeable, and its light transmittance may be configured according to the actual use requirements of the display panel. In some embodiments, the transitional display area 2 is light-transmissive, and the light transmittance of the transitional display area 2 is lower than the light transmittance of the transparent display area 10.

The light-emitting elements provided in the embodiments of the present disclosure may be, for example, organic light-emitting diode (OLED) light-emitting elements, that is, the display panel is an OLED display panel. It is to be noted that the display panel of the embodiments of the present disclosure may also be other self-luminous display panels similar to the OLED display panel that may be driven in an active matrix (AM) manner.

A pixel-driving circuit 4 provided in the embodiments of the present disclosure refers to the smallest repetitive unit of the circuit structure that drives the corresponding light-emitting element(s) to emit light, which is only illustrated by a rectangular frame in FIG. 2. The specific structure of the pixel-driving circuit 4 may be, for example, a 2T1C circuit, a 7T1C circuit, a 7T2C circuit, an 8T1C circuit, etc. In this disclosure, a “2T1C circuit” refers to a pixel circuit that includes two thin-film transistors (T) and one capacitor (C). Other “7T1C circuit”, “7T2C circuit” and the like are similarly annotated. The transistors may all be P-type or all N-type, or some are N-type and some are P-type.

FIG. 2 to FIG. 6 exemplarily show two first regular display areas 31, and along the first direction X, the transitional display area 2 is configured between a first regular display area 31 and the transparent display area 10. Along the second direction Y, the width of the first regular display area 31 is equal to the width of the wiring area 1. In the second direction Y, the number of levels of pixel-driving circuit 4 in a first regular display area 31 is a first number of levels N1, and the number of levels of pixel-driving circuit 4 in the transitional display area 2 is a second number of levels N2. The difference between the first number of levels N1 and the second number of levels N2 is configured to be less than a predefined number, which may be, for example, equal to or less than ½ of the first number of levels N1.

In some embodiments, referring to FIG. 2, in the second direction Y, the number of levels of pixel-driving circuit 4 in a first regular display area 31 is a first number of levels N1, where the first number of levels N1 is, for example, 10. The number of levels of pixel-driving circuit 4 in the transitional display area 2 is a second number of levels N2, where the second number of levels N2 is, for example, 6. This means that the difference between the first number of levels N1 and the second number of levels N2 is 4, which is less than ½ of the first number of levels N1. In other embodiments, referring to FIG. 3, in the second direction Y, the number of levels of pixel-driving circuit 4 in a first regular display area 31 is, for example, 10, and the number of levels of pixel-driving circuit 4 in the transitional display area 2 is, for example, 7.

That is, the difference between the first number of levels N1 and the second number of levels N2 is 3, which is less than ½ of the first number of levels N1. In other embodiments, referring to FIG. 4, in the second direction Y, the number of levels of pixel-driving circuit 4 in a first regular display area 31 is, for example, 10, and the number of levels of pixel-driving circuit 4 in the transitional display area 2 is, for example, 8. That is, the difference between the first number of levels N1 and the second number of levels N2 is 2, which is less than ½ of the first number of levels N1. In other embodiments, referring to FIG. 5, in the second direction Y, the number of levels of pixel-driving circuit 4 in a first regular display area 31 is, for example, 10, and the number of levels of pixel-driving circuit 4 in the transitional display area 2 is, for example, 9. That is, the difference between the first number of levels N1 and the second number of levels N2 is 1, which is less than ½ of the first number of levels N1.

FIG. 6 exemplarily shows that in the second direction Y, the number of levels of pixel-driving circuit 4 in a first regular display area 31, i.e., the first number of levels N1, is 10, the number of levels of pixel-driving circuit 4 in a transitional display area 2, i.e., the second number of levels N2, is 10. The difference between the first number of levels N1 and the second number of levels N2 is 0.

Therefore, by setting the difference between the first number of levels and the second number of levels to be smaller than a predefined level, the number of levels of pixel-driving circuit 4 of the transitional display area 2 in the second direction Y is made close to the number of levels of pixel-driving circuit 4 of the regular display area 3 in the second direction Y, thereby avoiding the problem of color cast of the display panel due to excessive difference in the number of levels of pixel-driving circuit 4 in the second direction Y between the transitional display area 2 and the regular display area 3, thereby improving the display performance of the display panel.

It should be noted that the first direction X in the embodiments of the present disclosure may be, for example, a row direction of a display panel, and the second direction Y may be, for example, a column direction of the display panel. The first direction X and the second direction Y may be, for example, other directions intersecting each other. The angle between the first direction X and the second direction Y is not limited in the present disclosure.

Optionally, as shown in FIGS. 2 to 6, the regular display area 3 includes a second regular display area 32. Along the second direction Y, the second regular display area 32 is located on one side of the transparent display area 10 and the transitional display area 2. Along the first direction X, the width of the second regular display area 32 is the same as the sum of the widths of the transitional display area 2, the wiring area 1, and the transparent display area 10. Along the first direction X, an extended portion of the second regular display area 32 does not overlap with the first regular display area 31, and along the second direction Y, an extended portion of the second regular display area 32 does not overlap with the first regular display area 31. In the first direction X, the number of levels of pixel-driving circuit 4 in the second regular display area 32 is a third number, and the number of levels of pixel-driving circuit 4 in the transitional display area 2 is a fourth number, where the fourth number is smaller than the third number.

Specifically, as shown in FIG. 2, along the second direction Y, a second regular display area 32 is located on one side of the transparent display area 10 and the transitional display area 2. Taking the planar direction of FIG. 2 as an example, the second regular display area 32 in FIG. 2 to FIG. 6 is located on the lower side of the wiring area 1, the transparent display area 10, and the transitional display area 2. In some embodiments, along the second direction Y, another second regular display area 32 may also be located on the upper side of the transparent display area 10 and the transitional display area 2, which is not limited in the present disclosure. Exemplarily, the second regular display area 32 provided in the embodiments of the present disclosure is located between the two first regular display areas 31 shown in FIG. 2 to FIG. 6, and is located on one side of the wiring area 1, the transparent display area 10 and the transitional display area 2.

With reference to FIG. 6, it may be understood that in the second direction Y, the number of levels of pixel-driving circuit 4 in the first regular display area 31, i.e., the first number of levels N1, is N, and the number of levels of pixel-driving circuit 4 in the transitional display area 2, i.e., the second number of levels N2, is N. In the first direction X, the number of levels of pixel-driving circuit 4 in the second regular display area 32 is a third number, and FIG. 6 exemplarily shows that the third number is, for example, 2N. The number of levels of pixel-driving circuit 4 in the transitional display area 2 is a fourth number, where the fourth number is, for example, 2×½N=N, and the third number 2N is greater than the fourth number N. Thus, by reducing the number of levels of pixel-driving circuit 4 in the transitional display area 2 in the first direction X, space is reserved for the transparent display area 10 where the pixel-driving circuits 4 are not arranged, and the size of the pixel-driving circuits 4 does not need to be changed, which solves the problem that the pixel-driving circuits 4 cannot be compressed for a high PPI display panel and it is difficult to arrange the transparent display area 10, and simplifies the preparation process of the display panel.

FIG. 7 is a partial structure of another display panel in accordance with an embodiment of the present disclosure. Optionally, as shown in FIG. 7, among the pixel-driving circuits 4 in the transitional display area 2, at least one pixel-driving circuit 4 is electrically connected to at least two light-emitting elements 5.

For example, at least two light-emitting elements 5 may be located in the transparent display area 10, in the wiring area 1, or in the transitional display area 2. The embodiments of the present disclosure do not specifically limit the locations of the at least two light-emitting elements 5.

Specifically, FIG. 7 exemplarily shows four pixel-driving circuits 4 and eight light-emitting elements 5 in the transitional display area 2, where each pixel-driving circuit 4 is electrically connected to two light-emitting elements 5, and the anodes of the two light-emitting elements 5 are electrically connected. This structure performs a one-to-many design for a pixel-driving circuit 4. By electrically connecting one pixel-driving circuit 4 to at least two light-emitting elements 5, the number of levels of pixel-driving circuit 4 required to be set in the transitional display area 2 may be reduced, thereby reducing the area of the display panel to be occupied by the pixel-driving circuits 4, leaving more space for the layout of the transparent display area 10. In addition, the embodiments of the present disclosure may also use limited pixel-driving circuits 4 to drive more light-emitting elements 5, thereby improving the pixel density of the transparent display area 10, the wiring area 1, and the transitional display area 2, reducing the brightness difference and picture difference with the regular display area 3, and improving the display quality of the display panel.

It should be noted that the number of light-emitting elements 5 electrically connected to a pixel-driving circuit 4 may be configured according to the actual use requirements of the display panel, which is not limited in the present disclosure.

Optionally, in combination with FIGS. 6 and 7, a pixel-driving circuit 4 in the transitional display area 2 is configured to be a pixel-driving circuit 4 that drives N0 number of light-emitting elements, where N0 is an integer and N0≥2. The third number of levels and the fourth number of levels satisfy: N1=N0×N2, where N1 represents the third number of levels and N2 represents the fourth number of levels.

FIG. 7 exemplarily shows that a pixel-driving circuit 4 in the transitional display area 2 is configured as a one-drive-two pixel-driving circuit 4, that is, one pixel-driving circuit 4 is electrically connected to two light-emitting elements 5 to drive the two light-emitting elements 5 to emit light, and the anodes of the two light-emitting elements 5 are electrically connected with each other, thereby reducing the number of levels of pixel-driving circuit 4 required to be configured in the transitional display area 2. Referring to FIG. 7, when the pixel-driving circuit 4 is configured as a one-drive-two pixel-driving circuit 4, along the first direction X, the number of levels of pixel-driving circuit 4 in each transitional display area 2 on both sides of the transparent display area 10 is, for example, N/2, respectively, then the fourth number of levels is N2=2×N/2=N, and the third number of levels is N1=2×N2=2N. Thus, by setting a one-drive-N0 pixel-driving circuit 4, the number of levels of pixel-driving circuit 4 in the transitional display area 2 in the first direction X is reduced, and space is opened up for the transparent display area 10 on a display panel with ultra-high PPI or complex process that cannot compress the size of the pixel-driving circuit 4. In addition, the embodiments of the present disclosure may also utilize a limited number of levels of pixel-driving circuit 4 to drive more light-emitting elements 5, thereby improving the pixel density of the transparent display area 10, the wiring area 1 and the transitional display area 2, reducing the brightness difference and picture difference with the regular display area 3, and improving the display quality of the display panel.

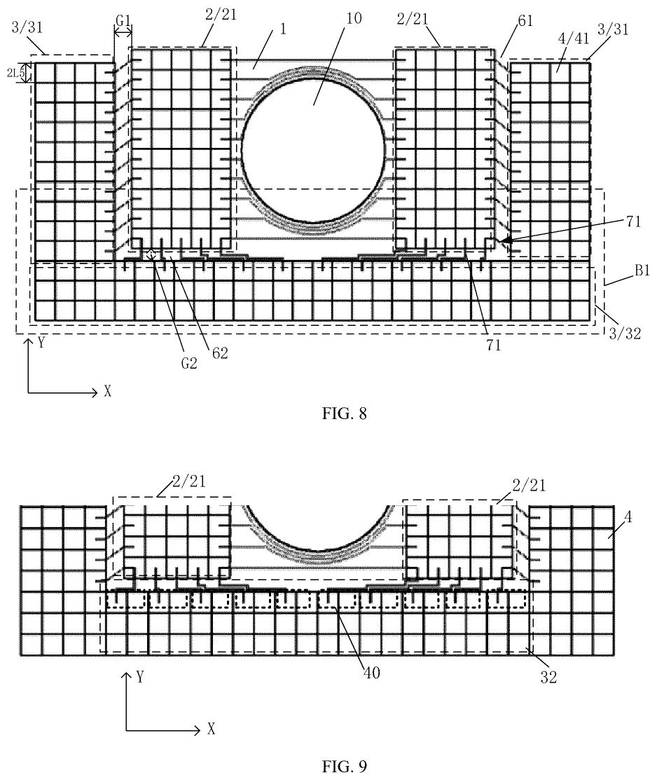

FIG. 8 is a partial structure of another display panel in accordance with an embodiment of the present disclosure. FIG. 9 is a schematic diagram of a partial enlargement of area B1 in FIG. 8. Optionally, in combination with FIG. 8 and FIG. 9, along the second direction Y, an i-th level of pixel-driving circuit 4 in the transitional display area 2 is correspondingly connected to one of the first number of levels of pixel-driving circuit 4 in the second regular display area 32, where i is an integer greater than or equal to 1 and less than or equal to the third level.

Specifically, in combination with FIGS. 8 and 9, in order to realize the driving of the light-emitting elements 5 by the pixel-driving circuits 4, along the second direction Y, the i-th level of pixel-driving circuit 4 in the transitional display area 2 is correspondingly connected to one level of pixel-driving circuit 4 in the second regular display area 32. Since in the first direction X, the number of levels of pixel-driving circuit 4 in the transitional display area 2 is less than the number of levels of pixel-driving circuit 4 in the second regular display area 32, therefore, i is an integer greater than or equal to 1 and less than or equal to the third level.

In order to realize the transmission of signals between the second regular display area 32 and the transitional display area 2, in some embodiments, the data signal line corresponding to the i-th level of pixel-driving circuit 4 in the transitional display area 2 may be electrically connected to the data signal line corresponding to one of the first-level of pixel-driving circuits 4 in the second regular display area 32, so as to realize the transmission of data signals between the second regular display area 32 and the transitional display area 2. In other embodiments, the power signal line corresponding to the i-th level of pixel-driving circuit 4 in the transitional display area 2 may also be electrically connected to the power signal line corresponding to one of the first-level of pixel-driving circuits 4 in the second regular display area 32, so as to realize the transmission of power signals between the second regular display area 32 and the transitional display area 2. It may be understood that the signal lines corresponding to the i-th level of pixel-driving circuit 4 in the transitional display area 2 and one of the first-level of pixel-driving circuits 4 in the second regular display area 32 may also be electrically connected to other signal lines transmitting signals along the second direction Y, which will not be described one by one here.

Optionally, as shown in FIG. 9, along the first direction X, the pixel-driving circuits 4 in the second regular display area 32 have at least N3 groups, and a group of pixel-driving circuits 4 include a number N4 of pixel-driving circuits 4. N3 is equal to the number of pixel circuits located in the transitional display area 2 along the first direction X, where N3≥1, and N3 is an integer. Along the first direction X, a j-th pixel-driving circuit 4 in each group of pixel-driving circuits 4 is connected to a pixel-driving circuit 4 in the transitional display area 2, where 1≤j≤N4, and j is an integer.

Exemplarily, FIG. 9 shows that along the first direction X, the pixel-driving circuits 4 in the second regular display area 32 are divided into ten groups, namely, ten pixel-driving circuit groups 40. FIG. 9 shows the pixel-driving circuit groups 40 in a dotted frame. Each group of pixel-driving circuits 4 includes two pixel-driving circuits 4. Taking FIG. 9 as an example, along the first direction X, the first pixel-driving circuit 4 in each group of pixel-driving circuits 4 is connected to a pixel-driving circuit 4 in the transitional display area 2. The numbers of levels of pixel-driving circuit 4 in the pixel-driving circuit groups 40 are consistent with the connection sequence of the pixel-driving circuits 4 in the transitional display area 2. The wiring of the display panel is performed according to this rule, which is conducive to simplifying the wiring process of the display panel, ensuring the consistency of the display panel process, and improving the manufacturing efficiency of the display panel. In addition, the data lines between the transitional display area 2 and the second regular display area 32 may be connected by connecting lines, for example. The wiring of the display panel according to this rule will also make the distribution of the connecting lines more uniform, thereby improving the display quality of the display panel.

It may be understood that when each pixel-driving circuit group 40 includes multiple pixel-driving circuits 4, it may be configured that, for example, the second pixel-driving circuit 4 in each pixel-driving circuit group 40 is connected to a pixel-driving circuit 4 in the transitional display area 2. The embodiments of the present disclosure do not specifically limit the order in which the pixel-driving circuits 4 in the second regular display area 32 and the pixel-driving circuits 4 in the transitional display area 2 are electrically connected.

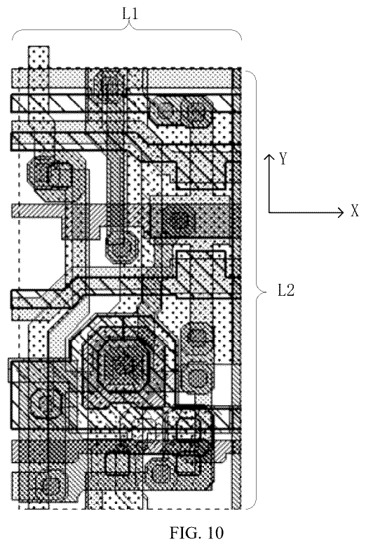

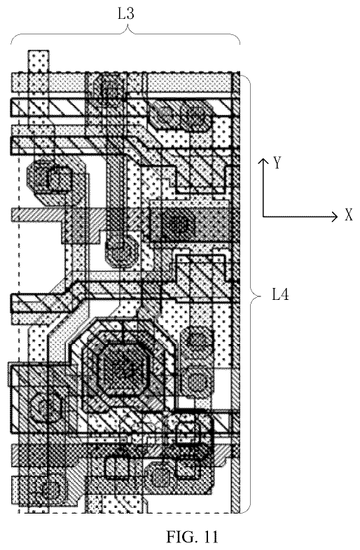

FIG. 10 is a schematic structural diagram of a pixel-driving circuit in a transitional display area in accordance with an embodiment of the present disclosure, and FIG. 11 is a schematic structural diagram of a pixel-driving circuit in a regular display area in accordance with an embodiment of the present disclosure. Optionally, in combination with FIG. 10 and FIG. 11, a pixel-driving circuit 4 in the transitional display area 2 has a first width L1 in the first direction X, and a second width L2 in the second direction Y; a pixel-driving circuit 4 in the regular display area 3 has a third width L3 in the first direction X, and a fourth width L4 in the second direction Y. The first width, the second width, the third width, and the fourth width satisfy: 90%*L1≤L3≤110%*L1 and 90%*L2≤L4≤110%*L2, where L1 represents the first width, L2 represents the second width, L3 represents the third width, and L4 represents the fourth width. The second direction Y intersects with the first direction X, and both are parallel to a plane where the display panel is located.

FIG. 10 shows a pixel-driving circuit 4 in the transitional display area 2, which has a first width L1 in the first direction X and a second width L2 in the second direction Y. FIG. 11 shows a pixel-driving circuit 4 in the regular display area 3, which has a third width L3 in the first direction X and a fourth width L4 in the second direction Y.

Exemplarily, according to the directions of FIG. 10, the first width L1 is, for example, a vertical distance from the left edge of the vertical projection of the film layer in a pixel-driving circuit 4 in the transitional display area 2 to the right edge of the vertical projection of the film layer on the substrate, and the second width L2 is, for example, a vertical distance from the upper edge to the lower edge of the vertical projection of the film layer of a pixel-driving circuit 4 in the transitional display area 2. According to the directions of FIG. 11, the third width L3 is, for example, a vertical distance from the left edge of the vertical projection of the film layer of a pixel-driving circuit 4 in the regular display area 3 to the right edge of the vertical projection of the film layer on the substrate, and the fourth width L2 is, for example, a vertical distance from the upper edge to the lower edge of the vertical projection of the film layer of a pixel-driving circuit 4 in the regular display area 3.

Exemplarily, the first width of a pixel-driving circuit 4 in the transitional display area 2 in the first direction X may be configured to be equal to the third width of a pixel-driving circuit 4 in the regular display area 3 in the first direction X within the process error range. The second width of a pixel-driving circuit 4 in the transitional display area 2 in the second direction Y may be configured to be equal to the fourth width of a pixel-driving circuit 4 in the transitional display area 2 in the second direction Y within the process error range. Therefore, relative to the size of a pixel-driving circuit 4 in the regular display area 3, there is no need to compress the size of a pixel-driving circuit 4 in the transitional display area 2, so that the size of a pixel-driving circuit 4 in the transitional display area 2 and the size of a pixel-driving circuit 4 in the regular display area 3 are as equal as possible within the process error range, thereby simplifying the preparation process of the display panel and avoiding the problem of being unable to layout the transparent display area 10 due to the inability to compress a pixel-driving circuit 4.

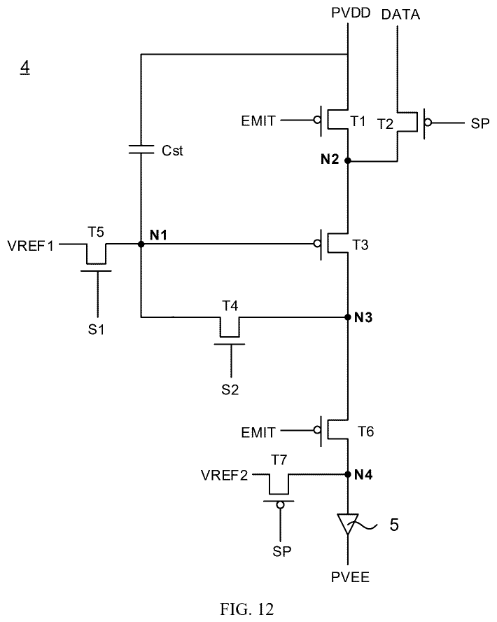

FIG. 12 is a schematic diagram of the circuit structure of a pixel-driving circuit in accordance with an embodiment of the present disclosure. As shown in FIG. 12, a pixel-driving circuit 4 includes seven transistors T1 to T7 and a capacitor Cst. The first light-emitting control transistor T1 and the second light-emitting control transistor T6 are turned off when the light-emitting control signal provided by the light-emitting control signal line EMIT is at a high level, and are turned on when the light-emitting control signal is at a low level, so that the light-emitting element 5 emits light in the light-emitting stage. The first reset transistor T5 is turned on when the first scanning signal provided by the first scanning signal line S1 is at a high level, and is configured to write the reference voltage signal provided by the reference signal line VREF1 to the first node N1. The data writing transistor T2 writes the data signal provided by the data signal line DATA to the driving transistor T3 when the third scanning signal provided by the third scanning signal line SP is at a low level, and the threshold compensation transistor T4 is turned on when the second scanning signal S2 provided by the second scanning signal line is at a low level. The second reset transistor T7 is turned on when the third scanning signal provided by the third scanning signal line SP is at a low level, and writes the anode reset signal provided by the anode reset signal line VREF 2 to the fourth node N4. Here, the second terminal of the first light-emitting control transistor T1, the first terminal of the driving transistor T3, and the first terminal of the data writing transistor T2 are all connected to the N2 node. The second terminal of the driving transistor T3, the second terminal of the threshold compensation transistor T4, and the first terminal of the second light-emitting control transistor T6 are all connected to the N3 node.

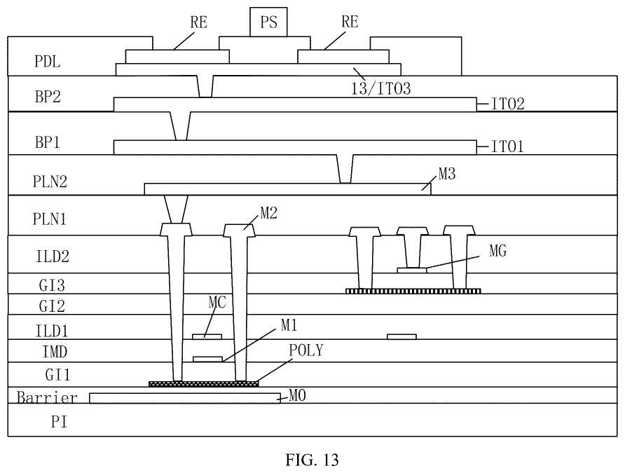

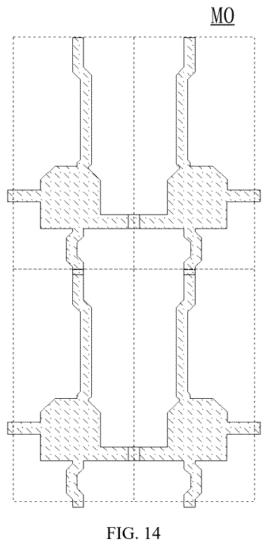

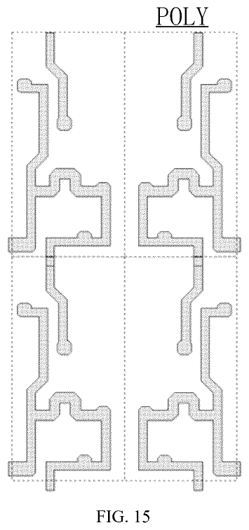

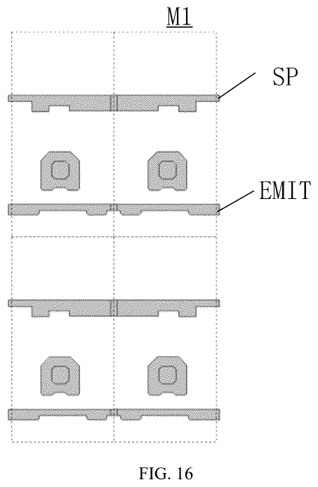

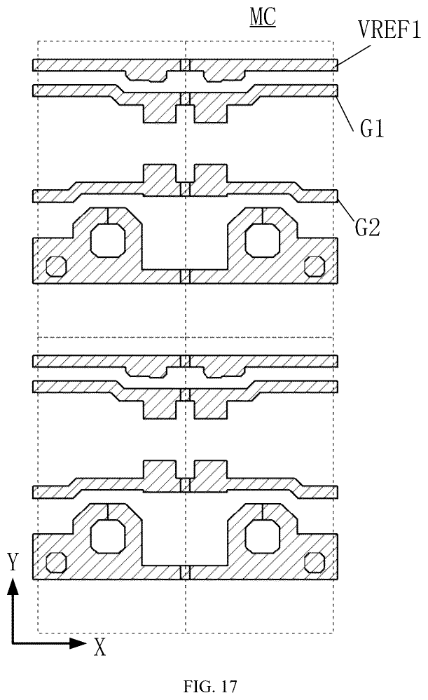

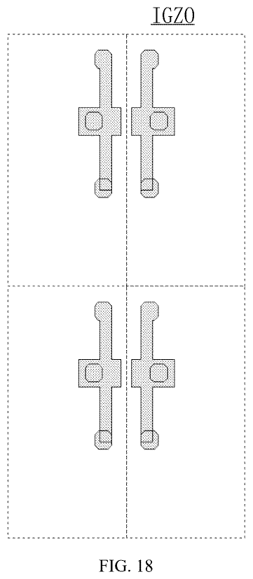

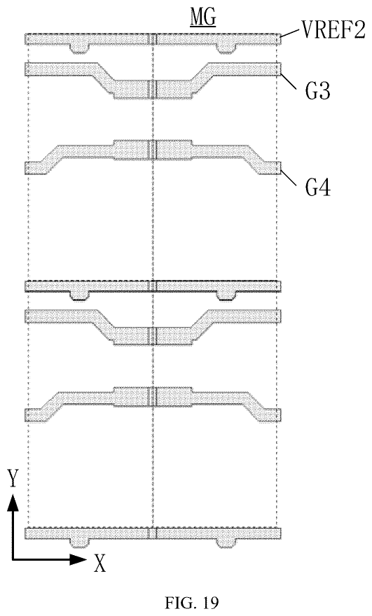

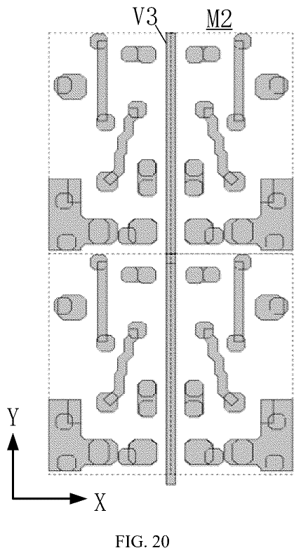

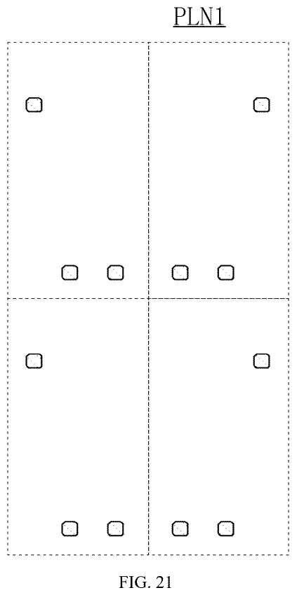

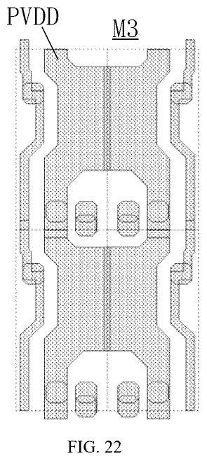

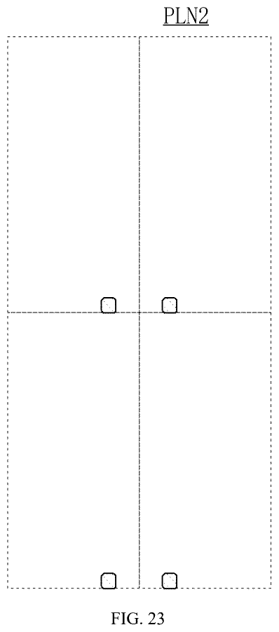

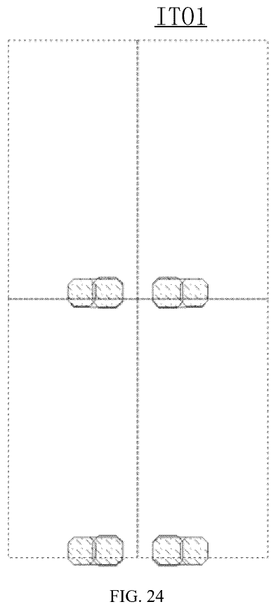

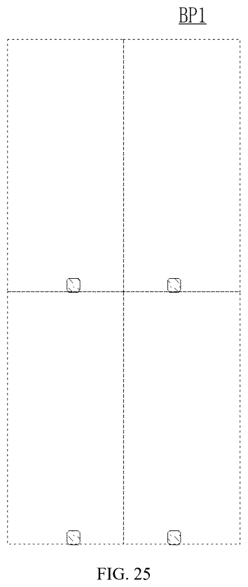

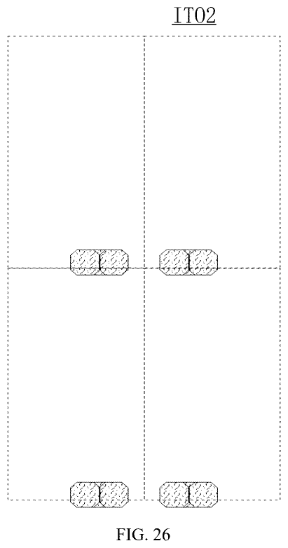

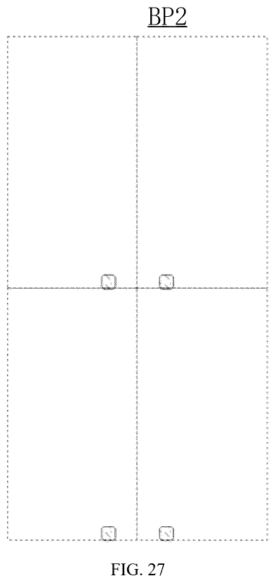

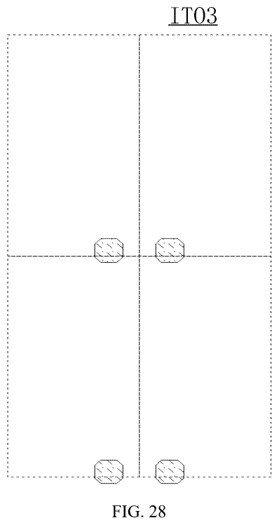

FIG. 13 is a schematic diagram of the cross-sectional structure of a display panel in accordance with an embodiment of the present disclosure, FIG. 14 is a schematic diagram of the planar structure of a bottom shielding metal layer of a driving repetitive unit in accordance with an embodiment of the present disclosure, FIG. 15 is a schematic diagram of the planar structure of a first active layer of a driving repetitive unit in accordance with an embodiment of the present disclosure, FIG. 16 is a schematic diagram of the planar structure of a first metal layer of a driving repetitive unit in accordance with an embodiment of the present disclosure, FIG. 17 is a schematic diagram of the planar structure of a capacitor metal layer of a driving repetitive unit in accordance with an embodiment of the present disclosure, FIG. 18 is a schematic diagram of the planar structure of a second active layer of a driving repetitive unit in accordance with an embodiment of the present disclosure, FIG. 19 is a schematic diagram of the planar structure of a second metal layer of a driving repetitive unit in accordance with an embodiment of the present disclosure, FIG. 20 is a schematic diagram of the planar structure of a third metal layer of a driving repetitive unit in accordance with an embodiment of the present disclosure, FIG. 21 is a schematic diagram of the planar structure of a first planarization layer of a driving repetitive unit provided in an embodiment of the present disclosure, FIG. 22 is a schematic diagram of the planar structure of a fourth metal layer of a driving repetitive unit in accordance with an embodiment of the present disclosure, FIG. 23 is a schematic diagram of the planar structure of a second planarization layer in accordance with an embodiment of the present disclosure, FIG. 24 is a schematic diagram of the planar structure of a first conductive layer in accordance with an embodiment of the present disclosure, FIG. 25 is a schematic diagram of the planar structure of a third planarization layer in accordance with an embodiment of the present disclosure, FIG. 26 is a schematic diagram of the planar structure of a second conductive layer in accordance with an embodiment of the present disclosure, FIG. 27 is a schematic diagram of the planar structure of a fourth planarization layer in accordance with an embodiment of the present disclosure, and FIG. 28 is a schematic diagram of the planar structure of a third conductive layer in accordance with an embodiment of the present disclosure.

In conjunction with FIGS. 12 to 28, the bottom shielding metal layer M0 is configured to shield the impurity ions at the bottom. The first metal layer M1 includes a third scan signal line SP for transmitting a third scan signal to control the on and off of the data write transistor and the second reset transistor T7, and the first metal layer M1 also includes a light-emitting control signal line EMIT. The capacitor metal layer MC may, for example, include a reference signal line VREF1, and a bottom gate G1 of the threshold compensation transistor T4 and a bottom gate G2 of the first reset transistor T5. The second metal layer MG includes, for example, an anode reset signal line VREF2, a bottom gate G3 of the threshold compensation transistor T4 and a bottom gate G2 of the first reset transistor T5.

The third metal layer M2 may be configured as a source and drain metal layer, for example. Exemplarily, the display panel may also include an auxiliary line V3, which extends along the second direction Y and may be connected to the reference signal line VREF1 extending along the first direction X for transmitting a reference signal. Additionally, or alternatively, the auxiliary line V3 may be connected to the anode reset signal line VREF2 extending along the first direction X for transmitting an anode reset signal. In this way, a grid connection may be achieved, and the voltage drop at different positions in the display panel may be balanced, which is conducive to improving display uniformity.

The fourth metal layer M3, for example, may be the layer where the power signal line PVDD is located. In addition, the display panel also includes a capacitor metal layer MC, and the capacitor metal layer MC and the first metal layer M1 may be configured to form a storage capacitor. The capacitor metal layer MC may also include a reset signal line VREF. The first active layer POLY may be, for example, a polysilicon layer, and the second active layer IGZO may be, for example, a metal oxide semiconductor layer. The first planarization layer PLN1, the second planarization layer PLN2, the third planarization layer BP1, and the fourth planarization layer BP2 may be, for example, organic layers for providing a flat surface for the display panel. The first conductive layer ITO1, the second conductive layer ITO2, or the third conductive layer ITO3 may, for example, be used as a transmission signal connection line 73 between the light-emitting elements 5.

Optionally, as shown in FIG. 8, the second number of levels is equal to the first number of levels. The pixel-driving circuits 4 in the transitional display area 2 are connected one-to-one with the pixel-driving circuits 4 in the first regular display area 31 according to the same level.

Specifically, as shown in FIG. 8, the embodiments of the present disclosure set the second number of levels to be equal to the first number of levels, for example, both are N levels as shown in FIG. 2. Exemplarily, along the direction from the transitional display area 2 to the first regular display area 31, the first regular display area 31 includes N levels of pixel-driving circuit 4, the transitional display area 2 includes, for example, N levels of pixel-driving circuit 4, and the n-th level of pixel-driving circuit 4 of the transitional display area 2 is electrically connected to the n-th level of pixel-driving circuit 4 of the first regular display area 31, where 1≤n≤N, and n and N are both positive integers.

In order to realize the transmission of signals between the first regular display area 31 and the transitional display area 2, in some embodiments, the light-emitting control signal line corresponding to the n-th level of pixel-driving circuit 4 of the transitional display area 2 may be electrically connected to the light-emitting control signal line corresponding to the n-th level of pixel-driving circuit 4 of the first regular display area 31, so as to realize the transmission of the light-emitting control signal between the first regular display area 31 and the transitional display area 2. In other embodiments, the reference signal line corresponding to the n-th level of pixel-driving circuit 4 of the transitional display area 2 may be electrically connected to the reference signal line corresponding to the n-th level of pixel-driving circuit 4 of the first regular display area 31, so as to realize the transmission of the reference signal between the first regular display area 31 and the transitional display area 2. In still other embodiments, the scanning signal line corresponding to the n-th level of pixel-driving circuit 4 of the transitional display area 2 may be electrically connected to the scanning signal line corresponding to the n-th level of pixel-driving circuit 4 of the first regular display area 31, so as to realize the transmission of the scanning signal between the first regular display area 31 and the transitional display area 2.

Accordingly, by connecting a pixel-driving circuit 4 in the transitional display area 2 with a pixel-driving circuit 4 in the first regular display area 31 in a one-to-one correspondence according to the same level, the wiring process is simplified, and the color cast problem of the display panel due to the large difference in the number of levels of pixel-driving circuit 4 in the second direction Y between the transitional display area 2 and the regular display area 3 is avoided, thereby optimizing the display performance of the display panel.

Optionally, as shown in FIG. 8, along the first direction X, there is a first gap 61 between the pixel-driving circuits 4 in the transitional display area 2 and the regular display area 3. Along the second direction Y, there is a second gap 62 between the pixel-driving circuits 4 in the transitional display area 2 and the regular display area 3. The first gap 61 and the second gap 62 satisfy: G1>G2, where G1 represents the width of the first gap 61 in the first direction X, and G2 represents the width of the second gap 62 in the second direction Y.

FIG. 8 exemplarily shows that the pixel-driving circuits 4 in the transitional display area 2 are translated along the first direction X so that there is a first gap 61 between the pixel-driving circuits 4 in the transitional display area 2 and the pixel-driving circuits 4 in the regular display area 3. The pixel-driving circuits 4 in the transitional display area 2 are translated along the second direction Y so that there is a second gap 62 between the pixel-driving circuits 4 in the transitional display area 2 and the pixel-driving circuits 4 in the regular display area 3. The first gap 61 is used to arrange the connection lines of the scanning signal lines, the light-emitting control signal lines, or the reference signal lines of the pixel-driving circuits 4 between the transitional display area 2 and the first regular display area 31, and the second gap 62 is used to arrange the connection lines of the data lines of the pixel-driving circuits 4 between the transitional display area 2 and the second regular display area 32. Therefore, by translating the pixel-driving circuits 4 in the transitional display area 2 along the first direction X and the second direction Y, there is no need to compress the pixel-driving circuits 4 in the transitional display area 2, and space may be reserved for the transparent display area 10, thereby simplifying the preparation process of the display panel.

Optionally, in combination with FIG. 8 and FIG. 11, a pixel-driving circuit 4 of the regular display area 3 has a fourth width in the second direction Y, and the width of the first gap 61 satisfies: G1<2*L4, where L4 represents the fourth width.

Specifically, in combination with FIGS. 8 and 11, a pixel-driving circuit 4 of the regular display area 3 has a fourth width of L4 in the second direction Y. In the first direction X, by setting the width of the first gap 61 between the pixel-driving circuits 4 in the transitional display area 2 and the pixel-driving circuits 4 in the regular display area 3 to be smaller than the width of the two pixel-driving circuits 4 in the regular display area 3 along the second direction Y, that is, 2*L4, the connecting lines of the data lines between the transitional display area 2 and the first display area 31 may be arranged in the first gap 61, and the transitional display area 2 may be prevented from exceeding the regular display area 3 too much that causes the problem of excessive area of the upper frame of the display panel, which is beneficial to reducing the frame area of the display panel.

Optionally, as shown in FIG. 8, the first type of connection lines 71 are provided in the first gap 61 and in the second gap 62. The first type of connection lines 71 connect the pixel-driving circuits 4 in the transitional display area 2 along the first direction X with the pixel-driving circuits 4 in the regular display area 3. The first type of connection lines 71 passing through the first gap 61 are used to transmit a first type of signal, and the first type of signal includes at least one of a reference signal, a scanning signal, and a light-emitting control signal. The first type of connection lines 71 passing through the second gap 62 are used to transmit a second type of signal, and the second type of signal includes a data signal.

Specifically, as shown in FIG. 8, the first type of connection lines 71 passing through the first gap 61 are used to connect the pixel-driving circuits 4 in the transitional display area 2 with the pixel-driving circuits 4 in the regular display area 3 along the first direction X. The first type of connection lines 71 passing through the first gap 61 may transmit, for example, one or more of a reference signal, a scan signal, and a light-emitting control signal. Therefore, the first type of connection lines 71 may be, for example, one or more of a reference signal VREF, a scan signal line SCAN, and a light-emitting control signal line EMIT. In some embodiments, the first type of connection lines 71 may also transmit other signals that need to be transmitted along the first direction X, which is not specifically limited in the present disclosure.

The first type of connection lines 71 passing through the second gap 62 are used to connect the pixel-driving circuits 4 in the transitional display area 2 and the pixel-driving circuits 4 in the regular display area 3 along the second direction Y. The first type of connection lines 71 passing through the second gap 62 may transmit data signals. In some embodiments, the first type of connection lines 71 may also transmit other signals that need to be transmitted along the second direction Y, which is not specifically limited in the present disclosure.

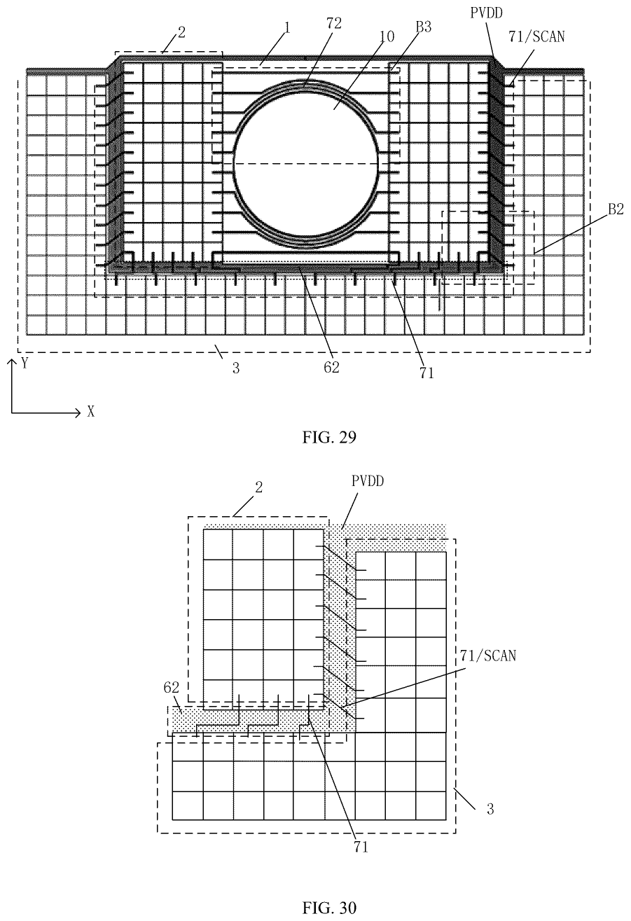

FIG. 29 is a schematic diagram of a partial structure of another display panel in accordance with an embodiment of the present disclosure, and FIG. 30 is a schematic diagram of a partial enlargement of area B2 in FIG. 29. Optionally, in combination with FIG. 29 and FIG. 30, power signal lines PVDD is further provided in the first gap 61. The power signal input terminal of a pixel-driving circuit 4 is connected to the power signal lines PVDD.

Specifically, in conjunction with FIG. 29 and FIG. 30, power signal lines PVDD are also arranged in the first gap 61 for transmitting a power signal, and the power signal lines PVDD extend to the transitional display area 2 and the regular display area 3, so that the pixel-driving circuits 4 of the transitional display area 2 and the pixel-driving circuits 4 of the regular display area 3 may access the power signal. As can be seen from FIG. 29 and FIG. 30, the area of a power signal line PVDD is larger than the area of a first type of connecting line 71. Since the density of the signal lines in the peripheral area, such as the scanning signal lines SCAN, is significantly higher than that in the regular display area 3 and the transitional display area 2, the load of the light-emitting elements in the regular display area 3 and the transitional display area 2 is higher than that in other areas, so the use of a large area of positive voltage power signal line PVDD may achieve signal shielding, which is conducive to reducing the disturbance of the signal lines in the peripheral area to the anode signal of the light-emitting elements 5, thereby improving the display performance of the display panel.

When the power signal lines PVDD and the first type of connection lines 71 are arranged on the same layer, due to the limited layout space, the wiring spacing is reduced, and short circuit is prone to occur between adjacent wirings. Therefore, the power signal lines PVDD and the first type of connection lines 71 are arranged to be distributed in different film layers so that the wiring of the power signal lines PVDD and the wiring of the first type of connection lines 71 do not interfere with each other. While avoiding the short circuit between the power signal lines PVDD and the first type of connection lines 71, it is also beneficial to simplify the wiring difficulty of the power signal lines PVDD and the first type of connection lines 71 and simplify the preparation process.

Optionally, in combination with FIGS. 29 and 30, the display panel also includes scanning signal lines SCAN, which are electrically connected to scanning signal receiving terminals of the pixel-driving circuits 4. In the first gap 61, in a direction perpendicular to the plane where the display panel is located, the power signal lines PVDD are located between the scanning signal lines SCAN and the light-emitting elements 5.

Specifically, in combination with FIG. 29 and FIG. 30, the display panel may further include scanning signal lines SCAN, the scanning signal lines SCAN extending along the first direction X and arranged along the second direction Y, the scanning signal lines SCAN being electrically connected to the scanning signal receiving terminals of the pixel-driving circuits 4 for transmitting the scanning signal. Since the density of the first type of connection lines 71 in the first gap 61, such as the scanning signal lines SCAN, is higher than the density of the transitional display area 2 and the regular display area 3, the signal connected to the light-emitting elements 5 in the first gap 61 is an anode signal, the voltage is positive, and the scanning signal lines SCAN are a high-frequency AC signal across positive and negative potentials. Therefore, in the first gap 61, in a direction perpendicular to the plane where the display panel is located, the power signal lines PVDD are arranged between the scanning signal lines SCAN and the light-emitting elements 5, and the power signal lines PVDD with a large area positive voltage is used to achieve signal shielding, which is conducive to reducing the disturbance of the scanning signal lines SCAN to the anode signal of the light-emitting elements 5, thereby improving the display performance of the display panel.

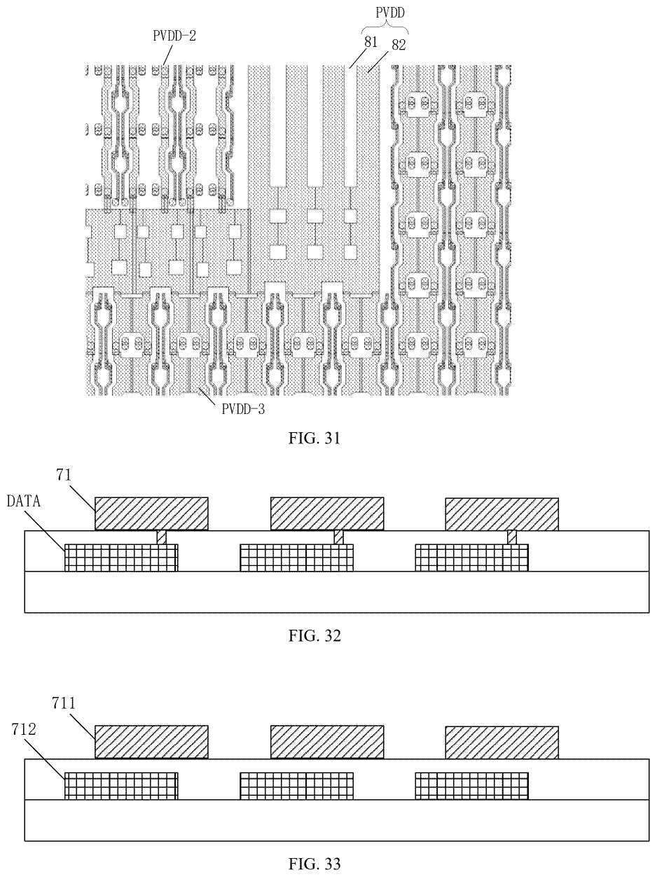

FIG. 31 is a schematic diagram of a planar structure of power signal lines in accordance with an embodiment of the present disclosure. Optionally, as shown in FIG. 31, a power signal line PVDD includes a hollow region 81 and a non-hollow region 82 that at least partially surrounds the hollow region 81. FIG. 31 exemplarily shows that the power signal lines PVDD-2 in the transitional display area 2 and the power signal lines PVDD-3 in the regular display area 3 are both electrically connected.

Specifically, as shown in FIG. 31, an opening may be provided on a power signal line PVDD to form a hollow region 81, such as a rectangular hole as shown in FIG. 31, and the power signal line PVDD further includes a non-hollow region 82 at least partially surrounding the hollow region 81. The material of the film layer where the power signal line PVDD is located is also retained in the non-hollow region 82. By adjusting the area size of the hollow region 81, the proportion of the area shielded by the power signal line PVDD is adjusted, thereby reducing the difference between the load of the light-emitting elements 5 of the first gap 61 and the load of the transitional display area 2 and the load of the regular display area 3.

Optionally, as shown in FIG. 31, the area of the hollow region 81 is a first area, the area of the non-hollow region 82 is a second area, and the first area and the second area satisfy: 20%≤S1/(S1+S2)≤80%, where S1 represents the first area, and S2 represents the second area. In FIG. 31, the non-hollow region 82 is represented by a filled shape.

Exemplarily, as shown in FIG. 31, the area proportion of the hollow region 81 to the sum of the first area and the second area may be set between 20% and 80%, for example. The anode of a light-emitting element 5 in the area outside the hollow region 81 will receive disturbance from signals such as scanning signals. If the hollow region 81 is too tight or does not conduct signal shielding at all, it will cause a difference between the load of the light-emitting element 5 and the load of the transitional display area 2 and the load of the regular display area 3. The area proportion of the hollow region 81 between 20% and 80% may reduce the difference between the load of the light-emitting element 5 in the first gap 61 and the load of the transitional display area 2 and the load of the regular display area 3, thereby improving the display performance of the display panel. It should be noted that the specific area proportion of the hollow region 81 may be configured according to the actual use of the display panel, which is not limited in the present disclosure. In addition, the specific shape of the hollow region 81 is not limited in the present disclosure.

FIG. 32 is a schematic diagram of a cross-sectional structure of a display panel in accordance with an embodiment of the present disclosure. Optionally, in combination with FIG. 29, FIG. 30 and FIG. 32, in the regular display area 3, the display panel further includes data lines DATA extending along the second direction Y and arranged along the first direction X. The first type of connection lines 71 passing through the second gap 62 connect the data lines DATA, and at least some of the first type of connection lines 71 are arranged in a different layer from the data lines DATA. In FIG. 32, the film layers are distinguished by different filling patterns.

Specifically, in conjunction with FIG. 29, FIG. 30, and FIG. 32, the first type of connection lines 71 passing through the second gap 62 are used to transmit a data signal, for example, so the first type of connection lines 71 in the second gap 62 are connected to the data lines DATA. The power signal lines PVDD and the data lines DATA may be configured in the same layer, and the power signal lines PVDD located in the wiring area 1, the transitional display area 2 and the regular display area 3 may be configured in the same layer. The first type of connection lines 71 passing through the second gap 62 cannot be configured in the same layer as the data lines DATA. If the data lines DATA and the first type of connection lines 71 are configured in a same film layer, due to the limited layout space, the wiring spacing is reduced, and the short circuit phenomenon is easy to occur between adjacent wirings. Therefore, when the first type of connection lines 71 and the data lines DATA are arranged in different film layers of the display panel, the first type of connection lines 71 and the data lines DATA may be electrically connected, for example through a via, so that the wiring of the data lines DATA and the wiring of the first type of connection lines 71 do not interfere with each other. While avoiding the short circuit phenomenon between the data lines DATA and the first type of connection lines 71, it is also beneficial to simplify the wiring difficulty of the data lines DATA and the first type of connection lines 71, and simplify the preparation process.

FIG. 33 is a schematic diagram of a cross-sectional structure of a display panel in accordance with an embodiment of the present disclosure. Optionally, in combination with FIG. 29, FIG. 30 and FIG. 33, the first type of connection lines 71 passing through the second gap 62 include first adapter lines 711 and second adapter lines 712. The first adapter lines 711 and the second adapter lines 712 are arranged in different layers.

Specifically, the first adapter lines 711 and the second adapter lines 712 may be used to transmit data signals. If the first adapter lines 711 and the second adapter lines 712 are both located in a same film layer, due to the limited layout space of the film layer, the distance between a first adapter line 711 and a second adapter line 712 will be too close, which increases the difficulty of manufacturing the first adapter lines 711 and the second adapter lines 712, and also increases the risk of short circuit between the first adapter lines 711 and the second adapter lines 712. In addition, if the distance between a first adapter line 711 and a second adapter line 712 is too close, the first adapter line 711 and the second adapter line 712 will be coupled, affecting the display performance of the display panel. Increasing the distance between the first adapter lines 711 and the second adapter lines 712 will cause too much film layer space to be occupied. Therefore, the embodiments of the present disclosure arrange the first adapter lines 711 and the second adapter lines 712 to be distributed in different film layers to avoid the problem of short circuit between the two types of lines, simplify the difficulty of manufacturing the first adapter lines 711 and the second adapter lines 712, and ensure that there is a larger interval between the first adapter lines 711 and the second adapter lines 712, thereby minimizing or avoiding the problem of signal coupling between the first adapter lines 711 and the second adapter lines 712.

In FIG. 33, the first adapter lines 711 and the second adapter lines 712 partially overlap in a direction perpendicular to the base substrate. The first adapter lines 711 and the second adapter lines 712 may also be arranged without overlapping, and may be arranged according to the actual space setting of the display panel, which are not limited in the present disclosure.

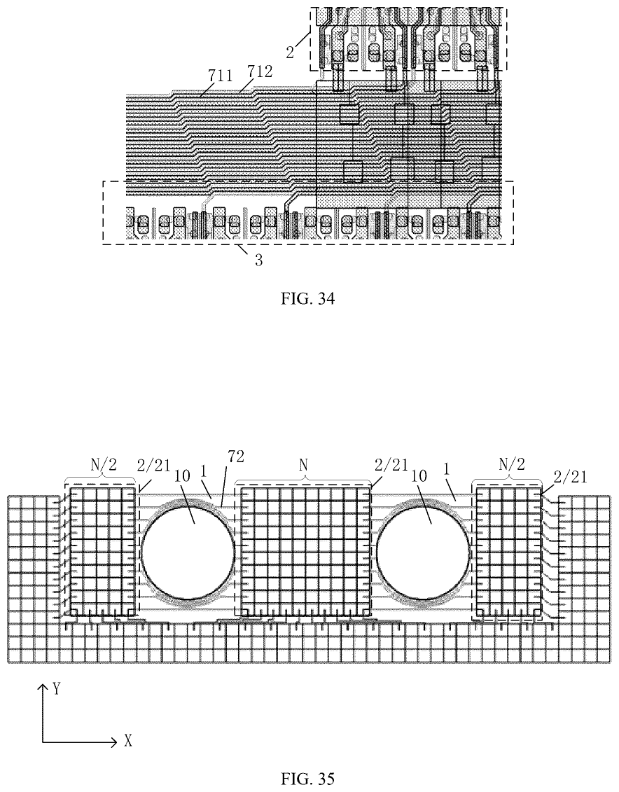

FIG. 34 is another partial enlarged schematic diagram of the area B2 in FIG. 29. Optionally, as shown in FIG. 34, in the plane where the display panel is located, the first adapter lines 711 and the second adapter lines 712 are alternately arranged.

Specifically, as shown in FIG. 34, due to the staggered arrangement of the regular display area 3 and the transitional display area 2, the first adapter lines 711 are required to be arranged in a stepped manner. The greater the number of the first type of connection lines 71, the larger the space occupied by the connection lines, i.e., the spacing of the second gaps 62. In order to reduce the space occupied by the second gaps 62, the first adapter lines 711 and the second adapter lines 712 may be arranged alternately and overlapping, which facilitates the wiring of the first adapter lines 711 and the second adapter lines 712 in a smaller wiring space, leaving more space for the transparent display area 10 and improving the display performance of the display panel.

Optionally, as shown in FIGS. 13 and 34, the display panel also includes a base substrate PI, a first metal layer M1, and a second metal layer MG. The first metal layer M1 is located between the base substrate PI and the second metal layer MG. The first metal layer M1 includes first adapter lines 711, and the second metal layer MG includes second adapter lines 712. The resistance value of the first metal layer M1 is in the same order of magnitude as the resistance value of the second metal layer MG.

Specifically, as shown in FIGS. 13 and 34, the substrate PI may be used to support the film layer disposed thereon, and the substrate PI may include a rigid substrate, such as glass, or silicon wafer, and may also include a flexible substrate, such as thin glass, stainless steel, polyimide, etc., which is not limited here. A first shielding layer and a second shielding layer, for example, may also be provided on the substrate PI to prevent charge crosstalk. The first metal layer M1 may be, for example, a gate metal layer of a low temperature polysilicon (LTPS) transistor of a polysilicon semiconductor layer, and the second metal layer MG may be, for example, a gate metal layer of an IGZO transistor of an oxide semiconductor layer. Since the resistance value of the first metal layer M1 is in the same order of magnitude as the resistance value of the second metal layer MG, the first adapter lines 711 and the second adapter lines 712 need to transmit a same signal, so the first adapter lines 711 are arranged on the first metal layer M1, and the second adapter lines 712 are arranged on the second metal layer MG. The resistance values of the film layers where the two are located are in the same order of magnitude, which may make the load magnitudes of the first adapter lines 711 and the second adapter lines 712 more consistent, so as to ensure the display uniformity of the display panel.

In some embodiments, the first adapter lines 711 may be arranged on the second metal layer MG, and the second adapter lines 712 may be arranged on the first metal layer M1, which is not limited in the present disclosure.

FIG. 35 is a schematic diagram of a partial structure of another display panel in accordance with an embodiment of the present disclosure. Optionally, in combination with FIG. 6, FIG. 8 and FIG. 35, along the first direction X, the transitional display area 2 includes at least two sub-transitional display areas 21. A transparent display area 10 is configured between two adjacent sub-transitional display areas 21.

FIG. 35 exemplarily shows that the display panel includes two transparent display areas 10 and three sub-transitional display areas 21. Two sub-transitional display areas 21 are located on both sides of a transparent display areas 10 along the first direction X. It should be noted that the number of sub-transitional display areas 21 in the transitional display area 2 may be configured according to the number of transparent display areas 10 in the display panel, ensuring that one transparent display area 10 is disposed between two adjacent sub-transitional display areas 21. The light-emitting elements 5 in the transparent display areas 10 may be driven to emit light by the pixel-driving circuits 4 in the sub-transitional display areas 21. The specific number of the sub-transitional display areas 21 is not limited in the present disclosure.

In some embodiments, the two sub-transitional display areas 21 are mirror-symmetrical structures along the second direction, and the two mirror-symmetrical sub-transitional display areas 21 together with a transparent display area 10 therebetween to form a complete structure, thereby reducing the gap in the regular display area 3.

Optionally, in combination with FIG. 6, FIG. 8 and FIG. 35, along the first direction X, the number of levels of pixel-driving circuit 4 in the first sub-transitional display area 21 is equal to the number of levels of pixel-driving circuit 4 in the last sub-transitional display area 21.

FIG. 6 and FIG. 8 exemplarily show two sub-transitional display areas 21, where the number of levels of pixel-driving circuit 4 in the first sub-transitional display area 21 is, for example, ½N, and the number of levels of pixel-driving circuit 4 in the second sub-transitional display area 21 is also, for example, ½N. FIG. 35 exemplarily shows three sub-transitional display areas 21, where the number of levels of pixel-driving circuit 4 in the first sub-transitional display area 21 is, for example, ½N, and the number of levels of pixel-driving circuit 4 in the last sub-transitional display area 21 is also, for example, ½N. Thus, a layout space may be reserved for the transparent display area(s) 10 in the display panel, and multiple transparent display areas 10 may be arranged, which is convenient for the layout of the display panel.

Optionally, as shown in FIG. 35, when the number of sub-transitional display areas 21 is equal to or greater than three, along the first direction X, the number of levels of pixel-driving circuit 4 in a middle sub-transitional display area 21 is equal to twice the number of levels of pixel-driving circuit 4 in the first sub-transitional display area 21.

FIG. 35 exemplarily shows that the number of sub-transitional display areas 21 is, for example, three. Along the first direction X, the number of levels of pixel-driving circuit 4 in the middle sub-transitional display area 21 (i.e., the second sub-transitional display area 21) is, for example, N, and the number of levels of pixel-driving circuit 4 in the first sub-transitional display area 21 is, for example, ½N. In some embodiments, when the number of sub-transitional display areas 21 is, for example, four, the number of levels of pixel-driving circuit 4 in the middle two sub-transitional display areas 21 may be, for example, both N, and the number of levels of pixel-driving circuit 4 in the first sub-transitional display area 21 and the number of levels of pixel-driving circuit 4 in the last sub-transitional display area 21 may be, for example, both ½N. Thus, by configuring the numbers of levels of pixel-driving circuit 4 in different sub-transitional display areas 21 along the first direction X, a layout space may be reserved for the transparent display area(s) 10 in the first direction X, and multiple transparent display areas 10 may be laid out, which is convenient for the layout of the display panel.

Optionally, in combination with FIGS. 6, 8, 29, and 35, the display panel also includes a second type of connection lines 72. The second type of connection lines 72 bypass the transparent display area 10. The second type of connection lines 72 connect the pixel-driving circuits 4 with the same level along the second direction Y in adjacent sub-transitional display areas 21.

Specifically, the second type of connection lines 72 in the display panel bypass the transparent display area 10 to avoid affecting the emission and incidence of light in the transparent display area 10. When the first sub-transitional display area 21 and the second sub-transitional display area 21 are, for example, adjacent sub-transitional display areas 21, the first number of levels of pixel-driving circuit 4 of the first sub-transitional display area 21 is connected to the first number of levels of pixel-driving circuit 4 of the second sub-transitional display area 21 through the second type of connection line 72, and the k-th level of pixel-driving circuit 4 of the first sub-transitional display area 21 is connected to the k-th level of pixel-driving circuit 4 of the second sub-transitional display area 21 through the second type of connection line 72, where 1≤k≤the fourth level, and k is an integer. Configuring the wiring of the display panel according to this rule is conducive to simplifying the wiring process and improving the manufacturing efficiency of the display panel.

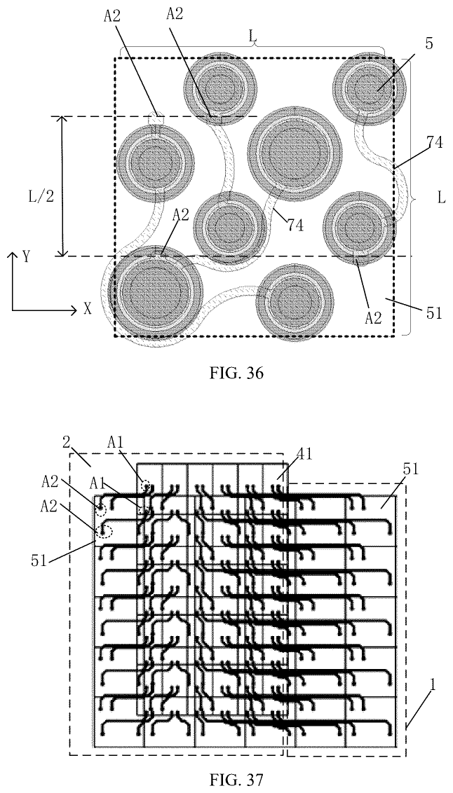

FIG. 36 is a schematic structural diagram of a light-emitting repetitive unit in accordance with an embodiment of the present disclosure, and FIG. 37 is a partially enlarged schematic diagram of area B3 in FIG. 29. Optionally, in combination with FIG. 36 and FIG. 37, eight light-emitting elements 5 form a light-emitting repetitive unit 51 in the transitional display area 2, the transparent display area 10, and the wiring area 1. The arrangement manner of the light-emitting repetitive units 51 in the transitional display area 2 is the same as the arrangement manner of the light-emitting repetitive unit 51 in the transparent display area 10. FIG. 25 only shows the light-emitting repetitive unit 51 in the transparent display area 10 in a rectangular frame.

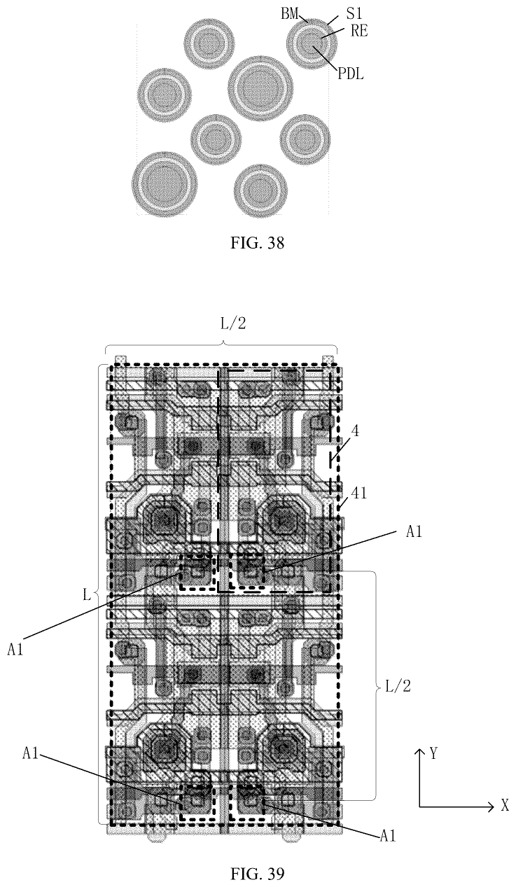

FIG. 38 is a schematic diagram of a film layer of a light-emitting repeating unit in accordance with an embodiment of the present disclosure. In combination with FIG. 36 and FIG. 38, the light-emitting repetitive unit 51 may include, for example, an anode layer RE, a pixel defining layer PDL, a photoresist layer BM, a color resist layer S1 and other film layers, and the light-emitting repetitive unit 51 is defined according to the periphery of the anode layer RE.

FIG. 36 exemplarily shows a light-emitting repetitive unit 51 including eight light-emitting elements 5. By way of example, a light-emitting repetitive unit 51 may have eight light-emitting sub-pixels, namely four green sub-pixels, two red sub-pixels, and two blue sub-pixels. Some sub-pixels in adjacent light-emitting repetitive units 51 may be shared. The sub-pixels in a light-emitting repetitive unit 51 may be located in different areas, which is related to the specific arrangement and the size of different areas, which is not limited in the present disclosure.

FIG. 37 exemplarily shows that in the transitional display area 2 and the wiring area 1, the arrangement manner of the light-emitting repetitive units 51 is similar. For example, the light-emitting repetitive units 51 in the wiring area 1 and the light-emitting repetitive units 51 in the transitional display area 2 may be arranged according to the arrangement illustrated in FIG. 36. This may reduce the display difference between the transitional display area 2 and the wiring area 1 caused by the different arrangements of the light-emitting repetitive units 51 in the wiring area 1 and in the transitional display area 2, thereby improving the display uniformity of the display panel. In addition, the same arrangement of the light-emitting repetitive units 51 in the wiring area 1 and in the transitional display area 2 also simplifies the preparation process of the display panel.

It should be noted that the number of light-emitting elements 5 included in a light-emitting repetitive unit 51 may be configured according to the actual display requirements of the display panel, which is not limited in the present disclosure.

FIG. 39 is a schematic structural diagram of a driving repetitive unit in accordance with an embodiment of the present disclosure. Optionally, in combination with FIG. 6, FIG. 8, FIG. 35, FIG. 37 and FIG. 39, in the transitional display area 2 and the regular display area 3, at least one pixel-driving circuit 4 forms a driving repetitive unit 41. The arrangement manner of the driving repetitive units 41 in the transitional display area 2 is the same as the arrangement manner of the driving repetitive units 41 in the regular display area 3. FIG. 37 shows that the transitional display area 2 includes the driving repetitive units 41 and the light-emitting repetitive units 51, and the transparent display area 10 includes only the light-emitting repetitive units 51.

FIG. 39 exemplarily shows that a driving repetitive unit 41 includes four pixel-driving circuits 4, and is arranged in the transitional display area 2 and the regular display area 3. The arrangement of the driving repetitive units 41 is the same. For example, in the regular display area 3, a driving repetitive unit 41 includes four pixel-driving circuits 4, which are arranged in two rows and two columns. In the transitional display area 2, a driving repetitive unit 41 includes four pixel-driving circuits 4, which are also arranged in two rows and two columns.

In some embodiments, a driving repetitive unit 41 includes, for example, pixel-driving circuits 4 arranged in an array of P×Q. The corresponding relationship of the number of levels is that: if the number of levels of driving repetitive unit 41 in the first direction X is N, then the number of levels of pixel-driving circuit 4 in the first direction X is P×N; if the number of levels of driving repetitive unit 41 in the second direction Y is N, then the number of levels of pixel-driving circuit 4 in the second direction Y is Q×N. When P is equal to Q, the ratio between the number of levels of driving repetitive unit 41 in the first direction X and the number of levels of driving repetitive unit 41 in the second direction Y is equal to the ratio between the number of levels of pixel-driving circuit 4 in the first direction X and the number of levels of pixel-driving circuit 4 in the second direction Y. P is the number of rows of first signal output terminal along the second direction Y, and Q is the number of columns of first signal output terminal along the first direction X. Referring to FIG. 7, FIG. 7 exemplarily shows that one pixel-driving circuit 4 drives two light-emitting elements 5 to emit light, and the anodes of each two light-emitting elements 5 are connected together, that is, four pixel-driving circuits 4 drive eight light-emitting elements 5 to emit light.

In this way, the driving difference between the transitional display area 2 and the regular display area 3 caused by the different arrangements of the driving repetitive units 41 may be reduced, thereby reducing the display difference caused by the driving difference, thereby improving the display uniformity of the display panel, and also simplifying the preparation process of the display panel.

It should be noted that the number of levels of pixel-driving circuit 4 included in a driving repetitive unit 41 may be configured according to the actual display requirements of the display panel, which is not limited in the present disclosure.

Optionally, in combination with FIGS. 36 and 39, along the second direction Y, the width of a driving repetitive unit 41 is equal to the width of a light-emitting repetitive unit 51. Additionally or alternatively, along the first direction X, the width of a driving repetitive unit 41 is smaller than the width of a light-emitting repetitive unit 51.

Specifically, FIG. 36 exemplarily shows that the width of the light-emitting repetitive unit 51 along the second direction Y is, for example, L, and the width L of the light-emitting repetitive unit 51 along the second direction Y is, for example, the vertical distance from the upper vertex of a light-emitting element 5 located at the upper edge of the light-emitting repetitive unit 51 to the lower vertex of a light-emitting element 5 at the lower edge of the light-emitting repetitive unit 51 in the directions of FIG. 36. FIG. 39 exemplarily shows that the width of the driving repetitive unit 41 along the second direction Y is, for example, L, and the width L of the driving repetitive unit 41 along the second direction Y is, for example, the vertical distance from the top edge of a pixel-driving circuit 4 located at the upper edge of the driving repetitive unit 41 to the bottom edge of a pixel-driving circuit 4 located at the lower edge of the driving repetitive unit 41 in the directions of FIG. 39. Thus, the width of a driving repetitive unit 41 along the second direction Y may be made equal to the width of a light-emitting repetitive unit 51 within a certain error range. In addition, the embodiments of the present disclosure may also set the width of a driving repetitive unit 41 along the first direction X to be smaller than the width of a light-emitting repetitive unit 51 along the first direction X. FIG. 36 exemplarily shows that the width of a light-emitting repetitive unit 51 along the first direction X is, for example, L. FIG. 39 exemplarily shows that the width of a driving repetitive unit 41 along the first direction X is, for example, L/2. By setting the width of the driving repetitive unit 41 along the first direction X to be smaller than the width of the light-emitting repetitive unit 51 along the first direction X, the driving repetitive unit 41 may be omitted from the transparent display area 10, leaving space for the layout of the transparent display area 10 in the display panel.

Optionally, in combination with FIGS. 7, 36, and 39, a pixel-driving circuit 4 in the transitional display area 2 is a pixel-driving circuit 4 that drives a number M1 of light-emitting elements. Along the first direction X, the width of a driving repetitive unit 41 is 1/M1 of the width of the light-emitting repetitive unit 51, where M1≥2, and M1 is an integer.

Exemplarily, FIG. 7 exemplarily shows that one pixel-driving circuit 4 drives two light-emitting elements 5 to emit light, and the anodes of each two light-emitting elements 5 are connected together. That is, the four pixel-driving circuits 4 shown in FIG. 39 drive the eight light-emitting elements 5 in FIG. 7 to emit light. When a pixel-driving circuit 4 in the transitional display area 2 is a one-drive-two pixel-driving circuit 4, along the first direction X, the width of a driving repetitive unit 41 is ½ of the width of a light-emitting repetitive unit 51, thereby reducing the space of the display panel occupied by the driving repetitive units 41, and more space may be provided for arranging the transparent display area 10. It should be noted that the specific value of M1 may be configured according to the actual display requirements of the display panel, which is not limited in the present disclosure.

Optionally, in combination with FIGS. 36 to 39, driving repetitive units 41 in the transitional display area 2 are connected to light-emitting repetitive units 51 in the transitional display area 2 and the transparent display area 10 in a one-to-one correspondence. In a driving repetitive unit 41 in the transitional display area 2, the number of levels of pixel-driving circuit 4 in each driving repetitive unit 41 is a first number of levels. In a light-emitting repetitive unit 51 in the transitional display area 2 or the transparent display area 10, the number of light-emitting elements 5 in each light-emitting repetitive unit 51 is a second number of levels, where the first number is less than the second number.

Specifically, as shown in FIG. 37, some of the driving repetitive units 41 in the transitional display area 2 are electrically connected to the light-emitting repetitive units 51 of the transitional display area 2, and are configured to drive the light-emitting elements 5 in the transitional display area 2 to emit light. Some of the driving repetitive units 41 in the transitional display area 2 are electrically connected to the light-emitting repetitive units 51 of the transparent display area 10, and are configured to drive the light-emitting elements 5 in the transparent display area 10 to emit light. Therefore, there is no need to configure the driving repetitive units 41 in the transparent display area 10, and the light-emitting elements 5 in the transparent display area 10 may also emit light.

Exemplarily, FIG. 36 exemplarily shows that a light-emitting repetitive unit 51 is composed of eight light-emitting elements 5, and FIG. 39 exemplarily shows that a driving repetitive unit 41 includes four pixel-driving circuits 4, so that one pixel-driving circuit 4 may drive two light-emitting elements 5 to emit light. Therefore, the number of levels of pixel-driving circuit 4 in each driving repetitive unit 41 is less than the number of light-emitting elements 5 in each light-emitting repetitive unit 51, which reduces the number of levels of pixel-driving circuit 4, thereby reducing the space of the display panel occupied by the pixel-driving circuits 4, and providing more space for the display panel to arrange the transparent display area 10.

Optionally, in combination with FIG. 36 and FIG. 37, a pixel-driving circuit 4 in the transitional display area 2 is a pixel-driving circuit 4 that drives a number M2 of light-emitting elements. The first number of levels (i.e., the number of levels of pixel-driving circuit 4 in each driving repetitive unit 41) is 1/M2 of the second number (i.e., the number of light-emitting elements 5 in each light-emitting repetitive unit 51), where M2≥2, and M2 is an integer.

Exemplarily, in combination with FIGS. 36 and 37, a pixel-driving circuit 4 in the transitional display area 2 is, for example, a one-drive-two pixel-driving circuit 4, that is, one pixel-driving circuit 4 may drive two light-emitting elements 5 to emit light, then the number of levels of pixel-driving circuit 4 in each driving repetitive unit 41 is half the number of light-emitting elements 5 in each light-emitting repetitive unit 51. By setting a one-drive-M2 pixel-driving circuit 4, the pixel-driving circuits 4 in the transitional display area 2 may be reduced by a magnitude of M2, thereby also reducing the number of levels of pixel-driving circuit 4, and further reducing the space of the display panel occupied by the pixel-driving circuits 4.

It should be noted that M2 may be the same integer as M1, or an integer different from M1, and may be set according to actual display requirements of the display panel, which is not limited in the present disclosure.

Optionally, as shown in FIGS. 7 and 39, the pixel-driving circuits 4 in a driving repetitive unit 41 is arranged in a P×Q array, where, M2×P×Q=R, R represents the second number, P≥1, Q≥1, and P and Q are both integers.

Exemplarily, FIG. 7 and FIG. 39 illustrate that the pixel-driving circuits 4 in a driving repetitive unit 41 are arranged in a 2×2 array, and the pixel-driving circuits 4 in the transitional display area 2 provided in the embodiments of the present disclosure are one-drive-two pixel-driving circuits 4, then the number of light-emitting elements 5 in each light-emitting repetitive unit 51 is R=2×2×2=8. Accordingly, one driving repetitive unit 41 provided in the embodiments of the present disclosure may drive eight light-emitting elements 5 to emit light, thereby greatly reducing the number of levels of pixel-driving circuit 4.

It should be noted that P and Q may be the same integer or different integers, and the specific numbers of M2, P and Q may be configured according to actual display requirements, which is not limited in the present disclosure.

Optionally, in combination with FIGS. 37 and 39, a pixel-driving circuit 4 includes a first signal output terminal A1, and the first signal output terminal A1 is connected to a light-emitting element 5. Along the second direction Y, the first signal output terminal A1 is located on a side of the pixel-driving circuit 4 close to the regular display area 3.

Specifically, in conjunction with FIG. 37 and FIG. 39, a pixel-driving circuit 4 is electrically connected to a light-emitting element 5 through the first signal output terminal A1, and outputs a driving signal to the light-emitting element 5 to drive the light-emitting element 5 to emit light. In addition, since the pixel-driving circuit 4 has many components, has a complex structure, and occupies a large space, according to the layout of the components in the pixel-driving circuit 4, the first signal output terminal A1 may be disposed on a side of the pixel-driving circuit 4 close to the second regular display area 32 along the second direction Y, so as to reduce the process difficulty of wiring in the display panel.

Optionally, as shown in FIG. 39, a driving repetitive unit 41 includes P×Q first signal output terminals A1. Along the second direction Y, the distance between adjacent first signal output terminals A1 is equal to the width of a pixel-driving circuit 4.

Specifically, the pixel-driving circuits 4 in a driving repetitive unit 41 are arranged in a P×Q array. For example, each pixel-driving circuit 4 includes a first signal output terminal A1, and each driving repetitive unit 41 includes a number P×Q of first signal output terminals A1. FIG. 39 exemplarily shows that the pixel-driving circuits 4 in the driving repetitive unit 41 are arranged in a 2×2 array. One driving repetitive unit 41 includes 2×2 first signal output terminals A1, that is, the first signal output terminals A1 in one driving repetitive unit 41 are evenly divided into two rows. Along the second direction Y, the distance between adjacent first signal output terminals A1 is, for example, L/2, and the width of one pixel-driving circuit 4 is, for example, also L/2. Thus, by arranging the first signal output terminals A1 evenly, the process difficulty of wiring in the display panel is reduced.

Optionally, as shown in FIG. 36, a light-emitting repetitive unit 51 includes P×Q first signal input terminals A2, and the first signal input terminals A2 are electrically connected to the first signal output terminals A1 one by one. Along the second direction Y, the distance between adjacent first signal input terminals A2 is equal to the width of a pixel-driving circuit 4.

Specifically, as shown in FIG. 36, in order to realize the corresponding electrical connection between a light-emitting repetitive unit 51 and a driving repetitive unit 41, the light-emitting repetitive unit 51 includes P×Q first signal input terminals A2, which are arranged according to the P×Q first signal output terminals A1 in the driving repetitive unit 41, so that the first signal input terminals A2 are electrically connected to the first signal output terminals A1 in a one-to-one correspondence. The driving repetitive unit 41 drives the light-emitting repetitive unit 51 to emit light. FIG. 36 exemplarily shows that along the second direction Y, the distance between adjacent first signal input terminals A2 is, for example, L/2. By setting the distance between adjacent first signal input terminals A2 to be equal to the width of a pixel-driving circuit 4, the first signal input terminals A2 of the light-emitting repetitive unit 51 are evenly arranged, thereby reducing the process difficulty of wiring in the display panel.

Optionally, as shown in FIG. 36, a light-emitting repetitive unit 51 includes P×Q groups of light-emitting elements 5, and each group of light-emitting elements 5 includes M2 light-emitting elements 5 of the same color. The display panel also includes input signal connection lines 74. An input signal connection line 74 is connected between the M2 light-emitting elements 5 in each group of light-emitting elements 5.

Specifically, as shown in FIG. 36, since one light-emitting repetitive unit 51 includes P×Q first signal input terminals A2, the light-emitting repetitive unit 51 includes P×Q groups of light-emitting elements 5. That is, one first signal input terminal A2 is correspondingly arranged to one group of light-emitting elements 5, and a driving signal is input to one group of light-emitting elements 5 through one first signal input terminal A2. In addition, each group of light-emitting elements 5 is arranged to include a number M2 of light-emitting elements 5 of the same color, so that the light-emitting elements 5 of the same color are close to each other and are all driven by the same pixel-driving circuit 4 to emit light, so that the light-emitting brightness of the light-emitting elements 5 of the same color is also similar, thereby improving the display uniformity of the display panel.

In some embodiments, the display panel further includes input signal connection lines 74, and M2 light-emitting elements 5 in each group of light-emitting elements 5 are electrically connected through an input signal connection line 74, which is configured to transmit the signal output by the pixel-driving circuit 4 to the M2 light-emitting elements 5. FIG. 36 exemplarily shows that at least two adjacent light-emitting elements 5 are electrically connected through an input signal connection line 74. As shown in FIG. 36, at least part of an input signal connection line 74 extends non-linearly, so that at least part of the input signal connection line 74 extends irregularly, weakening the diffraction phenomenon caused by the ambient light entering through the transparent display area 10, thereby reducing the starburst in an image obtained by shooting with the under-screen camera.

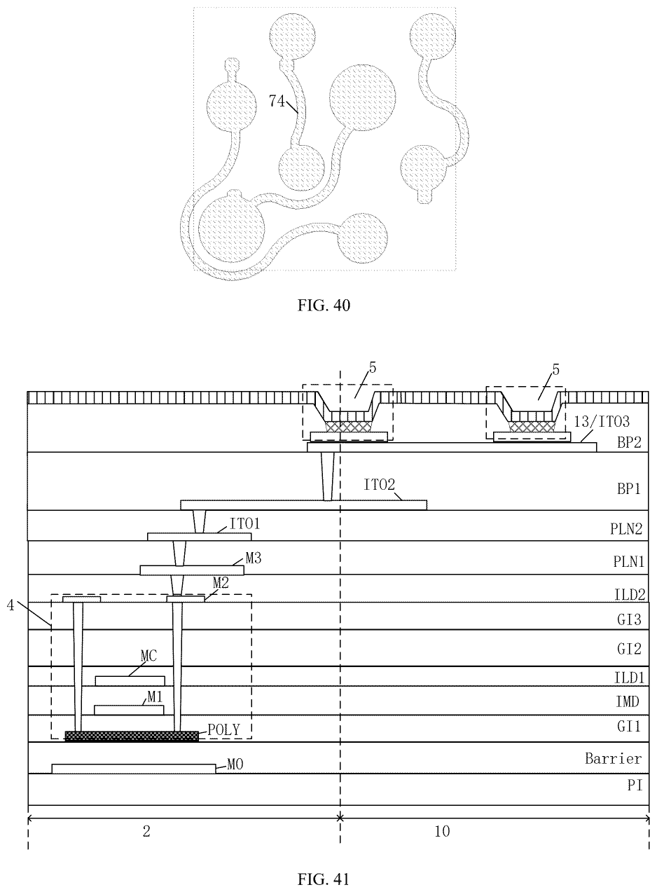

FIG. 40 is a schematic diagram of a film structure of a light-emitting repetitive unit in accordance with an embodiment of the present disclosure, and FIG. 41 is a schematic diagram of a film structure of a transitional display area to a transparent display area in accordance with an embodiment of the present disclosure. Optionally, in combination with FIG. 13, FIG. 36, FIG. 40 and FIG. 41, the display panel further includes a base substrate PI and functional film layers 13 stacked on one side of the base substrate. A functional film layer 13 for forming the input signal connection lines 74 is arranged in the same layer as a functional film layer 13 for forming the first signal input terminals A2.

It should be noted that FIG. 41 only illustrates some transistors in order to illustrate the connection from the transitional display area 2 to the transparent display area 10. For a specific schematic diagram of the film layers, refer to FIG. 13.

Specifically, in combination with FIGS. 13, 36, 40, and 41, a functional film layer 13 used to form the input signal connection lines 74 and a functional film layer 13 used to form the first signal input terminals A2 are arranged on the same layer. That is, the ports on the functional film layer 13 are used as the first signal input terminals A2. This portion of the input signal connection lines 74 and the first signal input terminals A2 may be manufactured in the same manufacturing process, and there is no need to electrically connect the input signal connection lines 74 with the first signal input terminals A2 by punching, which is conducive to simplifying the connection between this portion of the input signal connection lines 74 and the first signal input terminals A2, and simplifying the manufacturing process of the display panel.

Exemplarily, the functional film layer 13 may include a transparent conductive material. For example, the transparent conductive material may include at least one of indium tin oxide (ITO), indium zinc oxide (IZO), zinc oxide (ZnO), indium oxide (In₂O₃), gallium oxide (IGO), and aluminum zinc oxide (AZO). The transparent conductive material may not only realize the electrical connection between the pixel-driving circuits 4 and the light-emitting elements 5, but also will not affect the emission and incidence of light in the transparent display area 10.

Optionally, as shown in FIG. 37, along the second direction Y, the P×Q first signal output terminals A1 in a driving repetitive unit 41 include P rows of signal output terminals in a first plane. The P×Q first signal input terminals A2 in a light-emitting repetitive unit 51 include P rows of signal input terminals in a second plane. In a driving repetitive unit 41 and a light-emitting repetitive unit 51 that are connected, according to the order from 1 to P, the S-th row of signal output terminals A1 and the S-row signal input terminals A2 are sequentially arranged, where 1≤S≤P, and S is an integer, and the first plane is parallel to the second plane.

Specifically, as shown in FIG. 37, the driving repetitive unit 41 includes, for example, P rows of first signal output terminals A1, and each row of first signal output terminals A1 includes Q first signal output terminals A1. The light-emitting repetitive unit 51 includes, for example, P rows of first signal input terminals A2, and each row of first signal input terminals A2 includes Q first signal input terminals A2. The S-th row of first signal output terminals A1 in the driving repetitive unit 41 are electrically connected to the S-th row of first signal input terminals A2 in the light-emitting repetitive unit 51, to realize signal transmission.

Exemplarily, a first signal output terminal A1 of the first row is electrically connected to a first signal input terminal A2 of the first row, and a first signal output terminal A1 of the second row is electrically connected to a first signal input terminal A2 of the second row. Thus, by sequentially arranging the first signal output terminals A1 of the S-th row and the first signal input terminals A2 of the S-th row, the arrangement of the first signal output terminals A1 and the first signal input terminals A2 are made more regular, thereby reducing the wiring difficulty of the display panel.

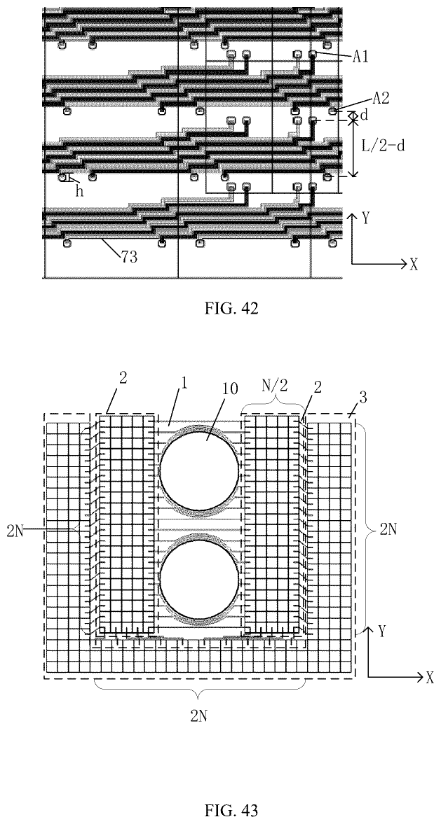

FIG. 42 is a schematic diagram of a partial structure of another display panel in accordance with an embodiment of the present disclosure. Optionally, in combination with FIG. 37 and FIG. 42, along the second direction Y, the minimum distance between the projections of a first signal input terminal A2 and a first signal output terminal A1 perpendicular to the base substrate is greater than or equal to a process distance, and less than or equal to a first predefined distance. Here, the process distance is the minimum distance that satisfies the non-interference of the graphics between the projections of the first signal input terminal A2 and the first signal output terminal A1 perpendicular to the substrate, and the first predefined distance is ¼ of the width of a pixel-driving circuit 4.

Exemplarily, the minimum distance that satisfies the non-interference of the graphics between the projections of the first signal input terminal A2 and the first signal output terminal A1 perpendicular to the substrate (i.e., the two graphics are not connected together) is s. FIG. 42 exemplarily shows that along the second direction Y, the minimum distance d between the second row of first signal input terminals A2 and the first row of first signal output terminals A1 is, for example, the sum of the process distance s and the via diameter h. In some embodiments, the process distance may be, for example, 2 microns, so the minimum distance may be configured to be greater than or equal to the process distance. In addition, the first predefined distance may also be set to be less than or equal to ¼ of the width of a pixel-driving circuit 4, thereby making the distance between the first signal input terminal A2 and the first signal output terminal A1 along the second direction Y as small as possible under the condition that the process allows, so that the center distance between the first signal output terminals A1 of a row below the driving repetitive unit 41 and the first signal input terminals A2 of a row below the light-emitting repetitive unit 51 along the second direction Y is as large as possible. This then allows as many connecting lines as possible to be arranged between the first signal input terminals A2 and the first signal output terminals A1, which helps to increase the size of the transparent display area 10.

Optionally, as shown in FIG. 42, along the second direction Y, the maximum distance between the first signal input terminals A2 and the first signal output terminals A1 is greater than or equal to a second predefined distance, and the second predefined distance is ⅓ of the width of a pixel-driving circuit 4.

FIG. 42 exemplarily shows that along the second direction Y, the maximum distance between the second row of first signal input terminals A2 and the second row of first signal output terminals A1 is, for example, L/2-d, and the maximum distance is greater than or equal to ⅓ of the width of a pixel-driving circuit 4. By increasing the maximum distance between the first signal input terminals A2 and the first signal output terminals A1, it is possible to arrange as many connecting lines as possible between the first signal input terminals A2 and the first signal output terminals A1, which helps to increase the size of the transparent display area 10.

Optionally, as shown in FIG. 42, the sum of the maximum distance and the minimum distance is equal to the width of a pixel-driving circuit 4 along the second direction Y.

FIG. 42 exemplarily shows that the maximum distance is L/2-d, and the minimum distance is d, then the sum of the maximum distance and the minimum distance is L/2, which is equal to the width of a pixel-driving circuit 4 along the second direction Y. This facilitates the arrangement of more connecting lines between the first signal input terminals A2 and the first signal output terminals A1, and helps to increase the size of the transparent display area 10 in the display panel.

It should be noted that the maximum distance, the minimum distance, and the specific width of a pixel-driving circuit 4 along the second direction Y may be configured according to the actual layout requirements of the display panel, and the embodiments of the present disclosure do not limit the specific size of each.

Optionally, in combination with FIGS. 7 and 42, the display panel also includes transmission signal connection lines 73, and the first signal input terminals A2 and the first signal output terminals A1 are connected one-to-one through the transmission signal connection lines 73. A transmission signal connection line 73 is arranged between a first signal output terminal A1 and a first signal input terminal A2 of a same row adjacent to each other along the second direction Y.

Exemplarily, a transmission signal connection line 73 may include multiple layers of conductive film layers. For example, as may be understood with reference to FIG. 13, a transmission signal connection line 73 may be located in the first conductive layer ITO1, the second conductive layer ITO2, or the third conductive layer ITO3. A first signal output terminal A1 may be, for example, a port of a via between the fourth metal layer M3 and the first conductive layer ITO1.

Specifically, in combination with FIGS. 7 and 42, the signal output by a pixel-driving circuit 4 is transmitted to a light-emitting element 5 through a first signal input terminal A2, a transmission signal connection line 73, and a first signal output terminal A1. The transmission signal connection line 73 is arranged, for example, between the first signal output terminal A1 of the S-th row and the first signal input terminal A2 of the S-th row. By increasing the distance between the first signal output terminals A1 and the first signal input terminals A2 as much as possible, more transmission signal connection lines 73 may be arranged, avoiding the transmission signal connection lines 73 occupying the space of the transparent display area 10, leaving more layout space for the transparent display area 10 of the display panel.

FIG. 43 is a partial structural diagram of another display panel in accordance with an embodiment of the present disclosure. Optionally, in combination with FIGS. 2 to 6, 8, 29, 35, and 43, the transparent display area 10 includes at least one sensor-setting area arranged along the second direction Y.

Specifically, FIGS. 2 to 6, 8, 29, and 35 exemplarily show that along the second direction Y, the transparent display area 10 includes one sensor-setting area, and FIG. 43 exemplarily shows that along the second direction Y, the transparent display area 10 may include two sensor-setting areas. FIG. 43 exemplarily shows that along the second direction, the number of levels of pixel-driving circuit 4 of the transitional display area 2 corresponding to each sensor-setting area is, for example, N levels, then the number of levels of pixel-driving circuit 4 of the transitional display area 2 corresponding to the two sensor-setting areas is, for example, 2N levels, and the number of levels of pixel-driving circuit 4 of the regular display area 3 is, for example, 2N levels. In other embodiments, there are two sensor-setting areas arranged along the second direction Y, and the number of levels of pixel-driving circuit 4 of the transitional display area 2 configured in one sensor-setting area is, for example, n1 levels, and the number of levels of pixel-driving circuit 4 of the transitional display area 2 configured in the other sensor-setting area is, for example, n2 levels, then the number of levels of pixel-driving circuit 4 of the transitional display area 2 corresponding to the two sensor-setting areas is, for example, (n1+n2) levels.

It should be noted that the number of sensor-setting areas in the transparent display area 10 may be configured according to the actual use requirements of the display panel, which is not limited in the present disclosure.

Exemplarily, a sensor may be disposed in at least one sensor-setting area 10, and the sensor may be, for example, an image acquisition apparatus for acquiring external image information. In some embodiments, the sensor may be a complementary metal oxide semiconductor (CMOS) image acquisition apparatus, and in other embodiments, the sensor may be a charge-coupled device (CCD) image acquisition apparatus or other forms of image acquisition apparatuses. It is understood that the sensor may not be limited to an image acquisition apparatus, and in some embodiments, the sensor may also be an infrared sensor, a proximity sensor, a fingerprint sensor or other sensors.

The display panel provided by the embodiments of the present disclosure sets the difference between the first number of levels and the second number of levels to be smaller than the predefined level, so that the number of levels of pixel-driving circuit in the first regular display area is close to the number of levels of pixel-driving circuit in the transitional display area, thereby avoiding the problem of color cast of the display panel caused by the transitional display area and the regular display area due to excessive difference in the numbers of levels of pixel-driving circuit between the transitional display area and the regular display area in the second direction. This not only leaves layout space for the transparent display area, but also improves the display performance of the display panel.

Based on the same inventive concept, the embodiments of the present disclosure also provide a display device, including a display panel as in any one of the above display panel embodiments. Therefore, the display device has the technical features of the display panel provided in the embodiments of the present disclosure, and may achieve the beneficial effects of the display panel provided in the embodiments of the present disclosure. For the similarities, refer to the above description of the display panels provided in the embodiments of the present disclosure, and no further description is given here.

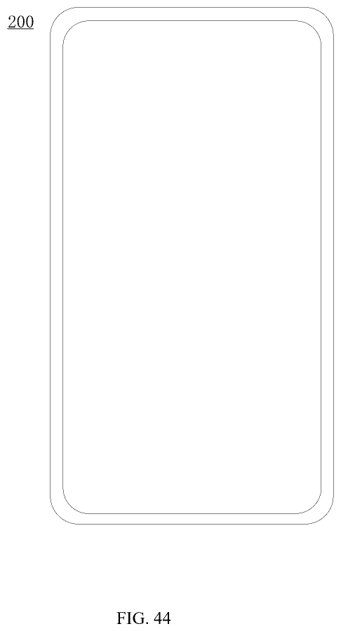

Exemplarily, FIG. 44 is a schematic structural diagram of a display device in accordance with an embodiment of the present disclosure. As shown in FIG. 44, the display device in accordance with an embodiment of the present disclosure includes a display panel 200 provided in any of the above embodiments of the present disclosure. The illustrated embodiment in FIG. 44 only takes a mobile phone as an example to illustrate the display device. It may be understood that the display device provided in the embodiments of the present disclosure may be any electronic product with a display function, including but not limited to the following categories: mobile phones, televisions, laptops, desktop displays, tablet computers, digital cameras, smart bracelets, smart glasses, car displays, medical equipment, industrial control equipment, touch interactive terminals, etc., which is not limited in the present disclosure.

The display device provided by the embodiments of the present disclosure includes the above-described display panels, and thus may solve the same technical problems as the above-described display panel embodiments and achieve the same technical.

For example, compared with the existing technologies, the technical solution provided by the present disclosure has the following advantages: for a display panel and a display device provided by the present disclosure, by setting the difference between the first number of levels and the second number of levels to be smaller than the predefined level, the number of levels of pixel-driving circuit in the first regular display area is made close to the number of levels of the pixel-driving circuit in the transitional display area, thereby avoiding the problem of color cast of the display panel caused by the transitional display area and the regular display area due to excessive difference in the number of levels of pixel-driving circuit in the transitional display area and the number of levels of pixel-driving circuit in the regular display area in the second direction, which not only leaves layout space for the transparent display area, but also improves the display performance of the display panel.

It should be noted that, in the disclosure, relational terms such as “first” and “second” are only used to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that a process, method, article or device including a series of elements includes not only those elements, but also other elements not explicitly listed, or also includes elements inherent to such process, method, article or device. In the absence of further restrictions, the elements defined by the sentence “comprise a . . . ” do not exclude the existence of other identical elements in the process, method, article or device including the elements.

The above are merely specific embodiments of the present disclosure, so that those skilled in the art may understand or implement the present disclosure. Various modifications to these embodiments will be apparent to those skilled in the art, and the general principles defined herein may be implemented in other embodiments without departing from the spirit or scope of the present disclosure. Therefore, the present disclosure will not be limited to these embodiments herein, but will conform to the widest scope consistent with the principles and novel features disclosed herein.

What is claimed is

1. A display panel, comprising:
a transparent display area, a wiring area, a transitional display area, and a regular display area, wherein the transitional display area at least partially surrounds the transparent display area, the regular display area at least partially surrounds the transitional display area and the transparent display area, a light transmittance of the transparent display area is greater than a light transmittance of the regular display area, and the wiring area is located between the transparent display area and the transitional display area and between the transitional display area and the regular display area; and
pixel-driving circuits and light-emitting elements electrically connected to the pixel-driving circuits, wherein the pixel-driving circuits are disposed in the transitional display area and the regular display area, and the light-emitting elements are at least disposed in the transparent display area, the transitional display area, and the regular display area, wherein:
the regular display area includes a first regular display area, along a first direction, the transitional display area is located between the first regular display area and the transparent display area, along a second direction, a number of levels of pixel-driving circuit in the first regular display area is a first number of levels, and a number of levels of pixel-driving circuit in the transitional display area is a second number of levels, the first direction is a direction from the transitional display area to the transparent display area, and the second direction intersects with the first direction, and
a difference between the first number of levels and the second number of levels is smaller than a predefined level, and the predefined level is equal to or smaller than ½ of the first number of levels.

2. The display panel according to claim 1, wherein:
the regular display area includes a second regular display area, and along the second direction, the second regular display area is located on one side of the transparent display area and the transitional display area;
along the first direction, pixel-driving circuits in the second regular display area have at least N3 groups, and one group of pixel-driving circuits includes N4 pixel-driving circuits, wherein N3 is equal to a number of pixel circuits located in the transitional display area along the first direction, N4≥1, and N4 is an integer; and
along the first direction, a j-th pixel-driving circuit in each group of pixel-driving circuits is connected to a pixel-driving circuit in the transitional display area, wherein 1≤j≤N4, and j is an integer.

3. The display panel according to claim 1, wherein:
a pixel-driving circuit in the transitional display area has a first width in the first direction and a second width in the second direction;
a pixel-driving circuit of the regular display area has a third width in the first direction and a fourth width in the second direction;
the first width, the second width, the third width and the fourth width satisfy: 90%*L1≤L3≤110%*L1 and 90%*L2≤L4≤110%*L2, wherein L1 represents the first width, L2 represents the second width, L3 represents the third width, and L4 represents the fourth width; and
the second direction intersects with the first direction, and both the first direction and the second direction are parallel to a plane where the display panel is located.

4. The display panel according to claim 1, wherein:
the second number of levels number is equal to the first number of levels; and
a pixel-driving circuit in the transitional display area is connected, in a one-to-one correspondence, with a pixel-driving circuit in the first regular display area based on a same level.

5. The display panel according to claim 1, wherein:
along the first direction, there is a first gap between the transitional display area and the regular display area, and along the second direction, there is a second gap between pixel-driving circuits in the transitional display area and the regular display area; and
the first gap and the second gap satisfy: G1>G2, wherein G1 represents a width of the first gap in the first direction, and G2 represents a width of the second gap in the second direction.

6. The display panel according to claim 5, wherein:
a pixel-driving circuit in the regular display area has a fourth width in the second direction; and
the first gap satisfies: G1<2*L4, wherein L4 represents the fourth width.

7. The display panel according to claim 5, wherein:
a power signal line is also arranged in the first gap; and
a power signal input terminal of a pixel-driving circuit is connected to the power signal line.

8. The display panel according to claim 7, further comprising a scanning signal line, wherein:
the scanning signal line is electrically connected to a scanning signal receiving terminal of the pixel-driving circuit; and
in the first gap, in a direction perpendicular to a plane where the display panel is located, the power signal line is located between the scanning signal line and a light-emitting element.

9. The display panel according to claim 7, wherein the power signal line comprises a hollow region and a non-hollow region at least partially surrounding the hollow region.

10. The display panel according to claim 6, wherein:
in the regular display area, the display panel further comprises data lines extending along the second direction and aligned along the first direction;
a first type of connection lines passing through the second gap are connected to the data lines, and at least some of the first type of connection lines and the data lines are disposed in different layers;
the first type of connection lines passing through the second gap includes first adapter lines and second adapter lines; and
the first adapter lines and the second adapter lines are disposed at different layers.

11. The display panel according to claim 10, further comprising a base substrate, a first metal layer and a second metal layer, wherein:
the first metal layer is located between the base substrate and the second metal layer; and
the first metal layer includes the first adapter lines, and the second metal layer includes the second adapter lines.

12. The display panel according to claim 1, wherein:
in the transitional display area and the transparent display area, eight light-emitting elements form a light-emitting repetitive unit, and an arrangement manner of light-emitting repetitive units in the transitional display area is the same as an arrangement manner of light-emitting repetitive units in the transparent display area;
in the transitional display area and the regular display area, four pixel-driving circuits form a driving repetitive unit, and an arrangement manner of driving repetitive units in the transitional display area is the same as an arrangement manner of driving repetitive units in the regular display area; and
along the second direction, a width of a driving repetitive unit is equal to a width of a light-emitting repetitive unit, and/or, along the first direction, a width of the driving repetitive unit is smaller than a width of the light-emitting repetitive unit.

13. The display panel according to claim 12, wherein:
the width of the light-emitting repetitive unit along the first direction and the width of the light-emitting repetitive unit along the second direction are equal; and
the width of the driving repetitive unit along the first direction is ½ of the width of the light-emitting repetitive unit along the first direction.

14. The display panel according to claim 12, wherein:
in the transitional display area and the regular display area, four pixel-driving circuits form a driving repetitive unit;
an arrangement manner of driving repetitive units in the transitional display area is the same as an arrangement manner of driving repetitive units in the regular display area;
one of the driving repetitive units includes a number P×Q of first signal output terminals; and
along the second direction, a distance between adjacent first signal output terminals is equal to a width of one pixel-driving circuit, wherein P is a number of rows of first signal output terminals along the second direction, and Q is a number of columns of first signal output terminals along the first direction.

15. The display panel according to claim 14, wherein:
one of the light-emitting repetitive units includes a number P×Q of first signal input terminals, and the first signal input terminals are electrically connected to the first signal output terminals in a one-to-one correspondence; and
along the second direction, a distance between adjacent first signal input terminals is equal to the width of one pixel-driving circuit.

16. The display panel according to claim 15, wherein:
one of the light-emitting repetitive units includes a number P×Q of groups of light-emitting elements, and each group of light-emitting elements includes a number M2 of light-emitting elements of a same color;
the display panel further includes an input signal connection line; and
the input signal connection line is connected between the number M2 of light-emitting elements in each group of light-emitting elements.

17. The display panel according to claim 15, wherein:
along the second direction, the number P×Q of first signal output terminals in one of the driving repetitive units include a number P rows of signal output terminals on a first plane;
the number P×Q of first signal input terminals in one of the light-emitting repetitive units include a number P rows of signal input terminals on a second plane, wherein the first plane is parallel to the second plane; and
in a driving repetitive unit and a light-emitting repetitive unit that are connected, an S-th row of signal output terminals and an S-th row of signal input terminals are sequentially arranged according to an order from 1 to P, wherein 1≤S≤P, and S is an integer.

18. The display panel according to claim 15, wherein along the second direction, a minimum distance between a projection of a first signal input terminal and a projection of a first signal output terminal perpendicular to a base substrate is greater than or equal to a process distance and less than or equal to a first predefined distance, wherein the process distance is a minimum distance that satisfies a non-interference of graphics the projection of the first signal input terminal and the projection of the first signal output terminal perpendicular to the base substrate, and the first predefined distance is ¼ of the width of one pixel-driving circuit.

19. The display panel according to claim 18, wherein along the second direction, a maximum distance between the first signal input terminal and the first signal output terminal is greater than or equal to a second predefined distance, wherein the second predefined distance is ⅓ of the width of one pixel-driving circuit.

20. A display device, comprising a display panel, the display panel including:
a transparent display area, a wiring area, a transitional display area, and a regular display area, wherein the transitional display area at least partially surrounds the transparent display area, the regular display area at least partially surrounds the transitional display area and the transparent display area, a light transmittance of the transparent display area is greater than a light transmittance of the regular display area, and the wiring area is located between the transparent display area and the transitional display area and between the transitional display area and the regular display area; and
pixel-driving circuits and light-emitting elements electrically connected to the pixel-driving circuits, wherein the pixel-driving circuits are disposed in the transitional display area and the regular display area, and the light-emitting elements are at least disposed in the transparent display area, the transitional display area, and the regular display area, wherein:
the regular display area includes a first regular display area, along a first direction, the transitional display area is located between the first regular display area and the transparent display area, along a second direction, a number of levels of pixel-driving circuit in the first regular display area is a first number of levels, and a number of levels of pixel-driving circuit in the transitional display area is a second number of levels, the first direction is a direction from the transitional display area to the transparent display area, and the second direction intersects with the first direction, and
a difference between the first number of levels and the second number of levels is smaller than a predefined level, and the predefined level is equal to or smaller than ½ of the first number of levels.
